(19) United States
(12) Patent Application Publication
(10) Pub. No.: US 2026/0324045 A1
(43) Pub. Date: Oct. 15, 2026

(54) MULTI-VT INTEGRATION SCHEMES FOR SEMICONDUCTOR DEVICES

(71) Applicant: Applied Materials, Inc., Santa Clara, CA (US)

(72) Inventors: Srinivas Gandikota, Santa Clara, CA (US); Hsin-Jung Yu, Santa Clara, CA (US); Geetika Bajaj, Cupertino, CA (US); Tuerxun Ailihumaer, Santa Clara, CA (US); Haodong Wang, Sunnyvale, CA (US); Yixiong Yang, Fremont, CA (US); Seshadri Ganguli, San Jose, CA (US); Yongjing Lin, San Jose, CA (US); Steven C.H. Hung, Sunnyvale, CA (US); Alexander Jansen, Danville, CA (US)

(73) Assignee: Applied Materials, Inc., Santa Clara, CA (US)

(21) Appl. No.: 19/178,534

(22) Filed: Apr. 14, 2025

(51) Int. Cl. H10D 84/01; H10D 30/01; H10D 62/10; H10D 64/66; H10D 64/68; H10D 30/00; H10D 30/43; H10D 84/83

(52) U.S. Cl. CPC H10D 84/014; H10D 30/014; H10D 30/019; H10D 62/102; H10D 62/121; H10D 64/663; H10D 64/669; H10D 64/685; H10D 64/691; H10D 30/43; H10D 30/502; H10D 84/83135; H10D 84/832

(57) ABSTRACT

Multiple threshold voltage (multi-Vₜ) integration schemes for electronic device manufacture are described. The integration schemes include forming a P-metal stack and an N-metal stack on a substrate; depositing at least one P-metal gate film on the P-metal stack; and depositing at least one N-metal gate film on the N-metal stack. Each of the at least one P-metal gate films independently include one or more of: a tunable thickness configured to provide multi-Vₜ, or a tunable composition, i.e., a binary metal nitride film or a ternary metal nitride film configured to provide multi-Vₜ. Each of the at least one N-metal gate films independently include one or more of: a tunable thickness configured to provide multi-Vₜ, or a tunable composition, i.e., a binary metal carbide film, a binary metal silicide film, a ternary metal carbide film, or a ternary metal silicide film configured to provide multi-Vₜ.

### TECHNICAL FIELD

Embodiments of the present disclosure pertain to the field of electronic device manufacturing. More particularly, embodiments of the disclosure are directed to multiple threshold voltage (multi-Vₜ) integration schemes for electronic device manufacture.

### BACKGROUND

Integrated circuits have evolved into complex devices that can include millions of transistors, capacitors, and resistors on a single chip. In the course of integrated circuit evolution, functional density (i.e., the number of interconnected devices per chip area) has generally increased while geometry size (i.e., the smallest component (or line) that can be created using a fabrication process) has decreased.

Transistors are circuit components or elements that are often formed on semiconductor devices. Many transistors may be formed on a semiconductor device in addition to capacitors, inductors, resistors, diodes, conductive lines, or other elements, depending on the circuit design. Integrated circuits incorporate planar field-effect transistors (FETs) in which current flows through a semiconducting channel between a source and a drain, in response to a voltage applied to a control gate.

As device dimensions have shrunk, device geometries and materials have experienced difficulty maintaining switching speeds without incurring failures. Several new technologies emerged that allowed chip designers to continue shrinking gate lengths. Control of the dimensions of device structure is a key challenge for present and future technology generations.

Scaling of the materials from 4 nm to 2 nm or 1.5 nm, for example, currently used as negative metal–oxide–semiconductor (N-MOS) transistors and positive metal–oxide–semiconductor (P-MOS) transistors, and changes in device architecture, have become a challenge due to change in basic properties, such as threshold voltage (Vₜ). Additionally, the migration of transistor technology from planar FET to FinFET to gate all-around (GAA) devices requires conformal work-function layers for multiple threshold voltages (multi-Vₜ).

In FinFET and the early generation of GAA device architectures, multi-Vₜ was achieved by 1) dipole density at the interfacial layer/high-ĸ dielectric layer interface or 2) thickness scaling of P-MOS and N-MOS work-function materials. The dipole density tuning at the interfacial layer/high-ĸ dielectric layer interface is costly since multiple patterning/annealing/removal steps are needed. The thickness scaling of the work function material is limited because there is limited space between each nanosheet, i.e., less than or equal to 4 nm. Accordingly, there is a need for new multi-Vₜ integration schemes.

### SUMMARY

One or more embodiments of the disclosure are directed to a method of manufacturing a semiconductor device. The method comprises forming a P-metal stack and an N-metal stack on a substrate. Each of the P-metal stack and the N-metal stack are formed on a channel located between a source and a drain on the substrate, each of the P-metal stack and the N-metal stack independently comprising an interfacial layer on the channel and a high-ĸ dielectric layer on the interfacial layer. The method comprises depositing at least one P-metal gate film on the P-metal stack, each of the at least one P-metal gate films independently including one or more of: a tunable thickness configured to provide multiple threshold voltages, or a binary metal nitride film or a ternary metal nitride film configured to provide multiple threshold voltages.

Additional embodiments of the disclosure are directed to a method of manufacturing a semiconductor device. The method comprises forming a P-metal stack and an N-metal stack on a substrate. Each of the P-metal stack and the N-metal stack are formed on a channel located between a source and a drain on the substrate, each of the P-metal stack and the N-metal stack independently comprising an interfacial layer on the channel and a high-ĸ dielectric layer on the interfacial layer. The method comprises depositing at least one N-metal gate film on the N-metal stack, each of the at least one N-metal gate films independently including one or more of: a tunable thickness configured to provide multiple threshold voltages, or a binary metal carbide film, a binary metal silicide film, a ternary metal carbide film, or a ternary metal silicide film configured to provide multiple threshold voltages.

Further embodiments of the disclosure are directed to a method of manufacturing a semiconductor device. The method comprises forming a P-metal stack and an N-metal stack on a substrate. Each of the P-metal stack and the N-metal stack are formed on a channel located between a source and a drain on the substrate, each of the P-metal stack and the N-metal stack independently comprising an interfacial layer on the channel and a high-ĸ dielectric layer on the interfacial layer. The method comprises depositing at least one P-metal gate film on the P-metal stack and depositing at least one N-metal gate film on the N-metal stack. Each of the at least one P-metal gate films independently include one or more of: a tunable thickness configured to provide multiple threshold voltages, or a binary metal nitride film or a ternary metal nitride film configured to provide multiple threshold voltages. Each of the at least one N-metal gate films independently include one or more of: a tunable thickness configured to provide multiple threshold voltages, or a binary metal carbide film, a binary metal silicide film, a ternary metal carbide film, or a ternary metal silicide film configured to provide multiple threshold voltages.

### BRIEF DESCRIPTION OF THE DRAWINGS

So that the manner in which the above recited features of the present disclosure can be understood in detail, a more particular description of the disclosure, briefly summarized above, may be had by reference to embodiments, some of which are illustrated in the appended drawings. It is to be noted, however, that the appended drawings illustrate only typical embodiments of this disclosure and are therefore not to be considered limiting of its scope, for the disclosure may admit to other equally effective embodiments. The embodiments as described herein are illustrated by way of example and not limitation in the Figures of the accompanying drawings in which like references indicate similar elements.

FIG. 1A illustrates a process flow diagram of a method of manufacturing a semiconductor device according to one or more embodiments of the disclosure;

FIG. 1B illustrates a process flow diagram of a method of manufacturing a semiconductor device according to one or more embodiments of the disclosure;

FIG. 1C illustrates a process flow diagram of a method of manufacturing a semiconductor device according to one or more embodiments of the disclosure;

FIG. 2A illustrates a cross-sectional view of a substrate according to one or more embodiments of the disclosure;

FIG. 2B illustrates a cross-sectional view of a P-metal stack and an N-metal stack on a substrate according to one or more embodiments of the disclosure;

FIG. 2C illustrates a cross-sectional view of a P-metal stack and an N-metal stack on a substrate according to one or more embodiments of the disclosure;

FIG. 2D illustrates a cross-sectional view of a P-metal stack and an N-metal stack on a substrate according to one or more embodiments of the disclosure;

FIG. 2E illustrates a cross-sectional view of a P-metal stack and an N-metal stack on a substrate according to one or more embodiments of the disclosure;

FIG. 2F illustrates a cross-sectional view of a P-metal stack and an N-metal stack on a substrate according to one or more embodiments of the disclosure;

FIG. 2G illustrates a cross-sectional view of a P-metal stack and an N-metal stack on a substrate according to one or more embodiments of the disclosure;

FIG. 2H illustrates a cross-sectional view of a P-metal stack and an N-metal stack on a substrate according to one or more embodiments of the disclosure;

FIG. 2I illustrates a cross-sectional view of a P-metal stack and an N-metal stack on a substrate according to one or more embodiments of the disclosure;

FIG. 2J illustrates a cross-sectional view of a P-metal stack and an N-metal stack on a substrate according to one or more embodiments of the disclosure;

FIG. 2K illustrates a cross-sectional view of a P-metal stack and an N-metal stack on a substrate according to one or more embodiments of the disclosure;

FIG. 2L illustrates a cross-sectional view of a P-metal stack and an N-metal stack on a substrate according to one or more embodiments of the disclosure;

FIG. 2M illustrates a cross-sectional view of a P-metal stack and an N-metal stack on a substrate according to one or more embodiments of the disclosure; and

FIG. 2N illustrates a cross-sectional view of a P-metal stack and an N-metal stack on a substrate according to one or more embodiments of the disclosure.

### DETAILED DESCRIPTION

Before describing several exemplary embodiments of the disclosure, it is to be understood that the disclosure is not limited to the details of construction or process steps set forth in the following description. The disclosure is capable of other embodiments and of being practiced or being carried out in various ways.

The term "about" as used herein means approximately or nearly and in the context of a numerical value or range set forth means a variation of ±15%, or less, of the numerical value. For example, a value differing by ±14%, ±10%, ±5%, ±2%, or ±1%, would satisfy the definition of about.

Spatially relative terms, such as "beneath," "below," "lower," "above," "upper" and the like, may be used herein for ease of description to describe one element's relationship to another element(s) or feature(s) as illustrated in the Figures. It will be understood that the spatially relative terms are intended to encompass different orientations of the structure (e.g., substrate) in use or operation in addition to the orientation depicted in the Figures. For example, if the substrate in the Figures is turned over, elements described as "below" or "beneath" other elements would then be oriented "above" the other elements. Thus, the exemplary term "below" may encompass both an orientation of above and below. The substrate may be otherwise oriented (rotated 90 degrees or at other orientations) and the spatially relative descriptors used herein interpreted accordingly.

The use of the terms "a" and "an" and "the" and similar referents in the context of describing the materials and methods discussed herein (especially in the context of the following claims) are to be construed to cover both the singular and the plural, unless otherwise indicated herein or clearly contradicted by context. Recitation of ranges of values herein are merely intended to serve as a shorthand method of referring individually to each separate value falling within the range, unless otherwise indicated herein, and each separate value is incorporated into the specification as if it were individually recited herein.

All methods described herein can be performed in any suitable order unless otherwise indicated herein or otherwise clearly contradicted by context. The use of any and all examples, or exemplary language (e.g., "such as") provided herein, is intended merely to better illuminate the materials and methods and does not pose a limitation on the scope unless otherwise claimed. No language in the specification should be construed as indicating any non-claimed element as essential to the practice of the disclosed materials and methods.

Reference throughout this specification to "one embodiment," "certain embodiments," "one or more embodiments," “some embodiments,” or "an embodiment" means that a particular feature, structure, material, or characteristic described in connection with the embodiment is included in at least one embodiment of the disclosure. Thus, the appearances of the phrases such as "in one or more embodiments," "in certain embodiments," "in some embodiments," "in one embodiment," or "in an embodiment" in various places throughout this specification are not necessarily referring to the same embodiment of the disclosure. In one or more embodiments, the particular features, structures, materials, or characteristics are combined in any suitable manner.

In the above description and illustrations and following description, numerous specific details, such as specific materials, chemistries, dimensions of the elements, etc., are set forth in order to provide thorough understanding of one or more of the embodiments of the present disclosure. It will be apparent, however, to one of ordinary skill in the art that one or more embodiments of the present disclosure may be practiced without these specific details. In other instances, semiconductor fabrication processes, techniques, materials, equipment, etc., have not been described in great detail to avoid unnecessarily obscuring this description.

Those of ordinary skill in the art, with the included description, will be able to implement appropriate functionality without undue experimentation.

As used in this specification and the appended claims, the term "substrate" and "wafer" are used interchangeably, both referring to a surface, or portion of a surface, upon which a process acts. It will also be understood by those skilled in the art that reference to a substrate can also refer to only a portion of the substrate, unless the context clearly indicates otherwise. Additionally, reference to "depositing on" or "forming on" a substrate can mean both a bare substrate and a substrate with one or more films or features deposited or formed thereon.

A "substrate" as used herein, refers to any substrate or material surface formed on a substrate upon which film processing is performed during a fabrication process. For example, a substrate surface on which processing can be performed include materials such as silicon, silicon oxide, strained silicon, silicon on insulator (SOI), carbon doped silicon oxides, amorphous silicon, doped silicon, germanium, gallium arsenide, and any other materials such as metals, metal nitrides, metal alloys, and other conductive materials, depending on the application. Substrates include, without limitation, semiconductor wafers. In some embodiments, the substrate comprises one or more of doped or undoped crystalline silicon (Si), doped or undoped crystalline silicon germanium (SiGe), doped or undoped amorphous silicon (Si), or doped or undoped amorphous silicon germanium (SiGe).

Substrates may be exposed to a pretreatment process to polish, etch, reduce, oxidize, hydroxylate, anneal and/or bake the substrate surface. In addition to film processing directly on the surface of the substrate itself, in the disclosure, any of the film processing steps disclosed may also be performed on an under-layer formed on the substrate as disclosed in more detail below, and the term "substrate surface" is intended to include such under-layer as the context indicates. Thus, for example, where a film/layer or partial film/layer has been deposited onto a substrate surface, the exposed surface of the newly deposited film/layer becomes the substrate surface.

The term "on" indicates that there is direct contact between elements. The term "directly on" indicates that there is direct contact between elements with no intervening elements.

As used herein, the term "in situ" refers to processes that are all performed in the same processing chamber or within different processing chambers that are connected as part of an integrated processing system, such that each of the processes are performed without an intervening vacuum break. As used herein, the term "ex situ" refers to processes that are performed in at least two different processing chambers such that one or more of the processes are performed with an intervening vacuum break. In some embodiments, processes are performed without breaking vacuum or without exposure to ambient air.

As used herein, the terms "precursor," "reactant," "reactive gas," "reactive species," and the like are used interchangeably to refer to any gaseous species that can react with the substrate surface.

As used herein, the term "chemical vapor deposition" refers to the exposure of at least one reactive species to deposit a layer of material on the substrate surface. In some embodiments, the chemical vapor deposition (CVD) process comprises mixing the two or more reactive species in the processing chamber to allow gas phase reactions of the reactive species and deposition. In some embodiments, the CVD process comprises exposing the substrate surface to two or more reactive species simultaneously. In some embodiments, the CVD process comprises exposing the substrate surface to a first reactive species continuously with an intermittent exposure to a second reactive species. In some embodiments, the substrate surface undergoes the CVD reaction to deposit a layer having a predetermined thickness. In the CVD process, the layer can be deposited in one exposure to the mixed reactive species or can be multiple exposures to the mixed reactive species with purges between. In some embodiments, the substrate surface is exposed to the first reactive species and the second reactive species substantially simultaneously.

As used herein, "substantially simultaneously" means that most of the duration of the first reactive species exposure overlaps with the second reactive species exposure.

As used herein, the term "purging" includes any suitable purge process that removes unreacted precursor, reaction products and by-products from the process region. The suitable purge process includes moving the substrate through a gas curtain to a portion or sector of the processing region that contains none or substantially none of the reactant. In one or more embodiments, purging the processing chamber comprises applying a vacuum. In some embodiments, purging the processing region comprises flowing an inert gas over the substrate. In one or more embodiments, the inert gas is selected from one or more of nitrogen (N₂), helium (He), and argon (Ar). In some embodiments, the first reactive species is purged from the reaction chamber for a time duration in a range of from 0.1 seconds to 30 seconds, for example, before exposing the substrate to the second reactive species.

"Cyclical deposition" or "atomic layer deposition" (ALD) refers to the sequential exposure of two or more reactive species to deposit a layer of material on a substrate surface. The substrate, or portion of the substrate, is exposed separately to the two or more reactive species which are introduced into a reaction zone of a processing chamber. In a time-domain ALD process, exposure to each reactive species is separated by a time delay to allow each compound to adhere and/or react on the substrate surface and then be purged from the processing chamber. These reactive species are said to be exposed to the substrate sequentially. In a spatial ALD process, different portions of the substrate surface, or material on the substrate surface, are exposed simultaneously to the two or more reactive species so that any given point on the substrate is substantially not exposed to more than one reactive species simultaneously. As used in this specification and the appended claims, the term "substantially" used in this respect means, as will be understood by those skilled in the art, that there is the possibility that a small portion of the substrate may be exposed to multiple reactive gases simultaneously due to diffusion, and that the simultaneous exposure is unintended.

Transistors are circuit components or elements that are often formed on semiconductor devices. Depending upon the circuit design, in addition to capacitors, inductors, resistors, diodes, conductive lines, or other elements, transistors are formed on a semiconductor device. Generally, a transistor includes a gate formed between a source region and a drain region. In one or more embodiments, the source region and the drain region each include a doped region of a substrate, such as a semiconductor substrate, and exhibit a doping profile suitable for a particular application. The gate is positioned over the channel region and includes a gate dielectric interposed between a gate electrode and the channel region in the substrate.

As used herein, the term "field effect transistor" or "FET" refers to a transistor that uses an electric field to control the electrical behavior of the device. Field effect transistors are voltage controlled devices where their current carrying ability is changed by applying an electric field. Field effect transistors generally display very high input impedance at low temperatures. The conductivity between the drain and source terminals is controlled by an electric field in the device, which is generated by a voltage difference between the body and the gate of the device. The FET’s three terminals are source (S), through which the carriers enter the channel; drain (D), through which the carriers leave the channel; and gate (G), the terminal that modulates the channel conductivity. Conventionally, current entering the channel at the source (S) is designated I_{S} and current entering the channel at the drain (D) is designated I_{D}. Drain-to-source voltage is designated V_{DS}. By applying voltage to gate (G), the current entering the channel at the drain (i.e. I_{D}) can be controlled.

The metal–oxide–semiconductor field-effect transistor (MOSFET) is a type of field-effect transistor (FET) and is used in integrated circuits and high speed switching applications. MOSFET has an insulated gate, whose voltage determines the conductivity of the device. This ability to change conductivity with the amount of applied voltage is used for amplifying or switching electronic signals. A MOSFET is based on the modulation of charge concentration by a metal–oxide–semiconductor (MOS) capacitance between a body electrode and a gate electrode located above the body and insulated from all other device regions by a gate dielectric layer. Compared to the MOS capacitor, the MOSFET includes two additional terminals (source and drain), each connected to individual highly doped regions that are separated by the body region. These regions can be either p or n type, but they are both of the same type, and of opposite type to the body region. The source and drain (unlike the body) are highly doped as signified by a "+" sign after the type of doping.

If the MOSFET is an n-channel or nMOS FET, then the source and drain are n+ regions and the body is a p-type substrate region. If the MOSFET is a p-channel or pMOS FET, then the source and drain are p+ regions and the body is a n-type substrate region. The source is so named because it is the source of the charge carriers (electrons for n-channel, holes for p-channel) that flow through the channel; similarly, the drain is where the charge carriers leave the channel.

A nMOS FET is made up of a n-type source and drain and a p-type substrate. When a voltage is applied to the gate, holes in the body (p-type substrate) are driven away from the gate. This allows forming an n-type channel between the source and the drain and a current is carried by electrons from source to the drain through an induced n-type channel. Logic gates and other digital devices implemented using NMOSs are said to have NMOS logic. There are three modes of operation in a NMOS called the cut-off, triode and saturation. Circuits with NMOS logic gates dissipate static power when the circuit is idling, since DC current flows through the logic gate when the output is low.

A pMOS FET is made up of p-type source and drain and a n-type substrate. When a positive voltage is applied between the source and the gate (negative voltage between gate and source), a p-type channel is formed between the source and the drain with opposite polarities. A current is carried by holes from source to the drain through an induced p-type channel. A high voltage on the gate will cause a PMOS not to conduct, while a low voltage on the gate will cause it to conduct. Logic gates and other digital devices implemented using PMOS are said have PMOS logic. PMOS technology is low cost and has a good noise immunity.

In a NMOS, carriers are electrons, while in a PMOS, carriers are holes. When a positive voltage is applied to the gate, NMOS will conduct, while PMOS will not. Furthermore, when a negative voltage is applied in the gate, NMOS will not conduct and PMOS will conduct. NMOS are considered to be faster than PMOS, since the carriers in NMOS, which are electrons, travel twice as fast as holes, which are the carriers in PMOS. But PMOS devices are more immune to noise than NMOS devices. Furthermore, NMOS ICs would be smaller than PMOS ICs (that give the same functionality), since the NMOS can provide one-half of the impedance provided by a PMOS (which has the same geometry and operating conditions).

As used herein, the term "fin field-effect transistor (FinFET)" refers to a MOSFET transistor built on a substrate where the gate is placed on two, three, or four sides of the channel or wrapped around the channel, forming a double gate structure. FinFET devices have been given the generic name FinFETs because the source/drain region forms "fins" on the substrate. FinFET devices have fast switching times and high current density.

As used herein, the term "gate all-around (GAA)," is used to refer to an electronic device, e.g., a transistor, in which the gate material surrounds the channel region on all sides. The channel region of a GAA transistor may include nano-wires or nano-slabs or nano-sheets, bar-shaped channels, or other suitable channel configurations known to one of skill in the art. In one or more embodiments, the channel region of a GAA device has multiple horizontal nanowires or horizontal bars vertically spaced, making the GAA transistor a stacked horizontal gate-all-around (hGAA) transistor.

As used herein, the term "nanowire" refers to a nanostructure, with a diameter on the order of a nanometer (10⁻⁹ meters). Nanowires can also be defined as the ratio of the length to width being greater than 1000. Alternatively, nanowires can be defined as structures having a thickness or diameter constrained to tens of nanometers or less and an unconstrained length. Nanowires are used in transistors and some laser applications, and, in one or more embodiments, are made of semiconducting materials, metallic materials, insulating materials, superconducting materials, or molecular materials. In one or more embodiments, nanowires are used in transistors for logic CPU, GPU, MPU, and volatile (e.g., DRAM) and non-volatile (e.g., NAND) devices. As used herein, the term "nanosheet" refers to a two-dimensional nanostructure with a thickness in a scale ranging from about 0.1 nm to about 1000 nm, or from 0.5 nm to 500 nm, or from 0.5 nm to 100 nm, or from 1 nm to 500 nm, or from 1 nm to 100 nm, or from 1 nm to 50 nm.

As used herein, "threshold voltage (Vₜ)" refers to the minimum gate-to-source voltage to create a conducting channel between the source and drain terminals, effectively turning a transistor "on." "Multiple threshold voltage(s)" or "multi-Vₜ" technology includes transistors with varying threshold voltage(s) (Vₜ) to optimize circuit performance and power consumption.

In FinFET and the early generation of GAA device architectures, multi-Vₜ was achieved by 1) dipole density at the interfacial layer/high-ĸ dielectric layer interface or 2) thickness scaling of P-MOS and N-MOS work-function materials. The dipole density tuning at the interfacial layer/high-ĸ dielectric layer interface is costly since multiple patterning/annealing/removal steps are needed. The thickness scaling of the work function material is limited because there is limited space between each nanosheet, i.e., less than or equal to 4 nm.

Embodiments of the disclosure are directed to methods of manufacturing semiconductor devices, including, but not limited to, logic devices and/or memory devices. Some embodiments are directed methods of manufacturing "PMOS" or "PFET" structures and/or "NMOS" or "NFET" structures. Some embodiments are directed to methods of manufacturing FinFET. Some embodiments are directed to methods of manufacturing GAA transistors.

Embodiments of the disclosure advantageously provide methods of manufacturing electronic devices that meet reduced thickness, reduced leakage, lower thermal budget, and Vₜ requirements (including multi-Vₜ), and have improved device performance and reliability.

Some embodiments advantageously provide multi-Vₜ integration schemes that are not dependent on thickness scaling of P-MOS and N-MOS work-function materials.

Some embodiments advantageously provide multi-Vₜ integration schemes that are not dependent on dipole density tuning at the interfacial layer/high-ĸ dielectric layer interface, such that a reduced number of patterning/removal (i.e., etching) steps are needed compared to processes that include dipole density tuning at the interfacial layer/high-ĸ dielectric layer interface. In processes that include dipole density tuning at the interfacial layer/high-ĸ dielectric layer interface to achieve multi-Vₜ, patterning a dipole cap layer and a dipole layer are needed, and this exposure to the dipole layer(s) can lead to oxidation of the dipole layer(s) which degrades the dipole properties. Advantageously, the multi-Vₜ integration schemes described herein, which are not dependent on dipole density tuning at the interfacial layer/high-ĸ dielectric layer interface, minimize the number of etches and resulting exposure to oxidation, and consequently result in improved device performance.

Advantageously, to reduce cost of fabrication, some embodiments include deposition of a dipole layer having a predetermined composition, as described herein, only once in each of the NMOS and PMOS to limit the number of patterning/removal (i.e., etching) steps to avoid degradation of dipole properties and/or device performance. In some embodiments, threshold voltage (Vₜ) adjustment is advantageously achieved by providing new materials for the work-function metal composition and/or tuning the work-function metal composition, e.g., the at least one P-metal gate film and/or the at least one N-metal gate film.

Some embodiments advantageously provide multi-Vₜ integration schemes that can be achieved in the scaled space between one or more nanosheets. Some embodiments advantageously provide methods that reduce leakage (J_{g}) in an electronic device.

The embodiments of the disclosure are described by way of the Figures, which illustrate semiconductor devices (e.g., transistors) and methods of manufacturing transistors in accordance with one or more embodiments of the disclosure. The processes shown are merely illustrative possible uses for the disclosed processes, and the skilled artisan will recognize that the disclosed processes are not limited to the illustrated applications.

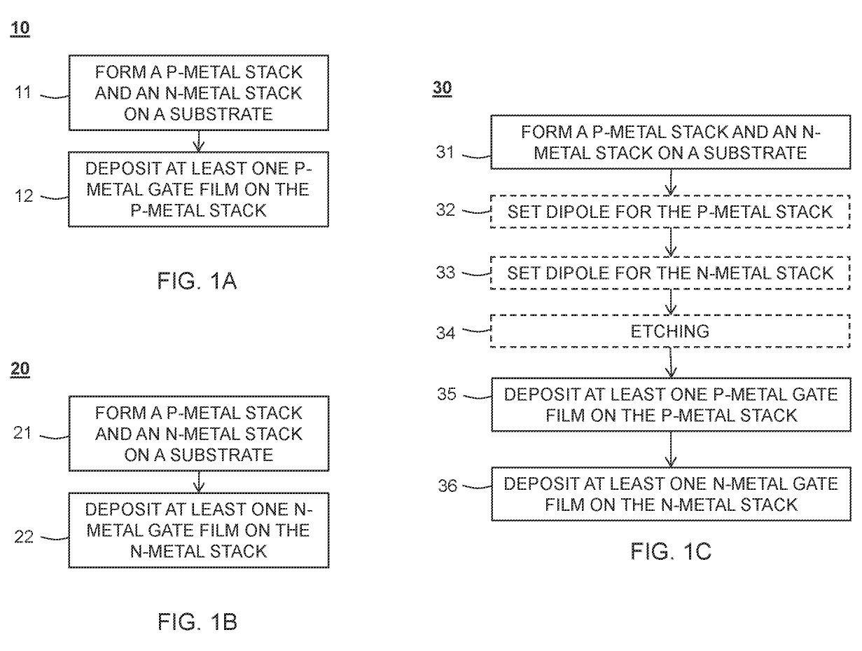

FIG. 1A illustrates a process flow diagram of a method 10 of manufacturing a semiconductor device according to one or more embodiments of the disclosure. FIG. 1B illustrates a process flow diagram of a method 20 of manufacturing a semiconductor device according to one or more embodiments of the disclosure. FIG. 1C illustrates a process flow diagram of a method 30 of manufacturing a semiconductor device according to one or more embodiments of the disclosure.

Referring to FIG. 1A, the method 10 comprises, consists essentially of, or consists of forming a P-metal stack and an N-metal stack on a substrate (operation 11); and depositing at least one P-metal gate film on the P-metal stack (operation 12). Each of the P-metal stack and the N-metal stack are formed on a channel located between a source region and a drain region on the substrate. Each of the P-metal stack and the N-metal stack independently comprise an interfacial layer on the channel and a high-ĸ dielectric layer on the interfacial layer. Each of the at least one P-metal gate films independently include one or more of: a tunable thickness configured to provide multiple threshold voltages, or a tunable composition, i.e., a binary metal nitride film or a ternary metal nitride film configured to provide multiple threshold voltages.

Referring to FIG. 1B, the method 20 comprises, consists essentially of, or consists of forming a P-metal stack and an N-metal stack on a substrate (operation 21); and depositing at least one N-metal gate film on the N-metal stack (operation 22). Each of the P-metal stack and the N-metal stack are formed on a channel located between a source region and a drain region on the substrate. Each of the P-metal stack and the N-metal stack independently comprise an interfacial layer on the channel and a high-ĸ dielectric layer on the interfacial layer. Each of the at least one N-metal gate films independently include one or more of: a tunable thickness configured to provide multiple threshold voltages, or a tunable composition, i.e., a binary metal carbide film, a binary metal silicide film, a ternary metal carbide film, or a ternary metal silicide film configured to provide multiple threshold voltages.

Referring to FIG. 1C, the method 30 comprises, consists essentially of, or consists of forming a P-metal stack and an N-metal stack on a substrate (operation 31); optionally, setting a dipole for the P-metal stack (operation 32); optionally, setting a dipole for the N-metal stack (operation 33); optionally, etching (operation 34); depositing at least one P-metal gate film on the P-metal stack (operation 35); and depositing at least one N-metal gate film on the N-metal stack (operation 36). In the method 30, operation 32, operation 33, and operation 34 are shown in dashed lines in FIG. 1C to denote that the stated operations are optional. Each of the P-metal stack and the N-metal stack are formed on a channel located between a source region and a drain region on the substrate. Each of the P-metal stack and the N-metal stack independently comprise an interfacial layer on the channel and a high-ĸ dielectric layer on the interfacial layer. Each of the at least one P-metal gate films independently include one or more of: a tunable thickness configured to provide multiple threshold voltages, or tunable composition, i.e., a binary metal nitride film or a ternary metal nitride film configured to provide multiple threshold voltages. Each of the at least one N-metal gate films independently include one or more of: a tunable thickness configured to provide multiple threshold voltages, or a tunable composition, i.e., a binary metal carbide film, a binary metal silicide film, a ternary metal carbide film, or a ternary metal silicide film configured to provide multiple threshold voltages.

In one or more embodiments, the method 30 comprises, consists essentially of, or consists of sequentially performing operation 31, operation 32, operation 33, operation 34, operation 35, and operation 36. In one or more embodiments, the method 30 comprises, consists essentially of, or consists of sequentially performing operation 31, operation 32, operation 33, operation 34, operation 36, and operation 35.

In one or more embodiments, the method 30 comprises, consists essentially of, or consists of sequentially performing operation 31, operation 33, operation 32, operation 34, operation 35, and operation 36. In one or more embodiments, the method 30 comprises, consists essentially of, or consists of sequentially performing operation 31, operation 33, operation 32, operation 34, operation 36, and operation 35.

In one or more embodiments, the method 30 comprises, consists essentially of, or consists of sequentially performing operation 31, operation 35, and operation 36. In one or more embodiments, the method 30 comprises, consists essentially of, or consists of sequentially performing operation 31, operation 36, and operation 35.

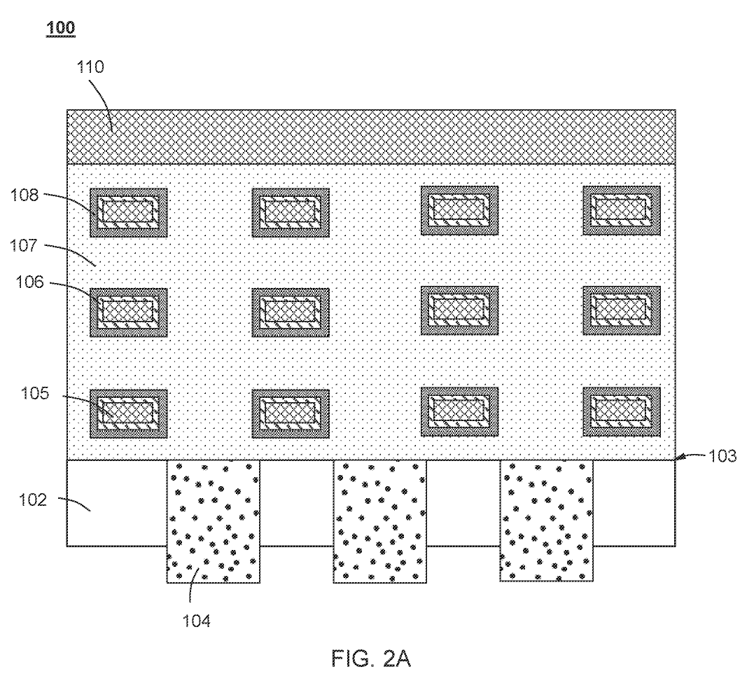

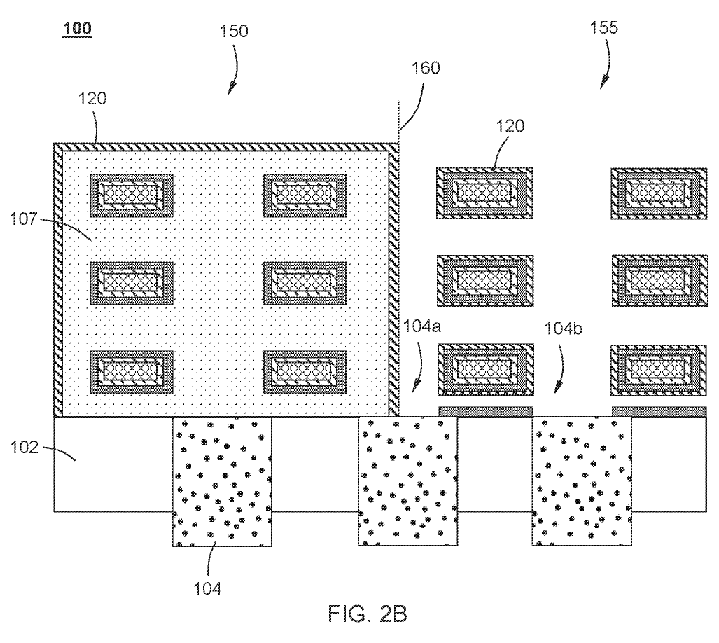

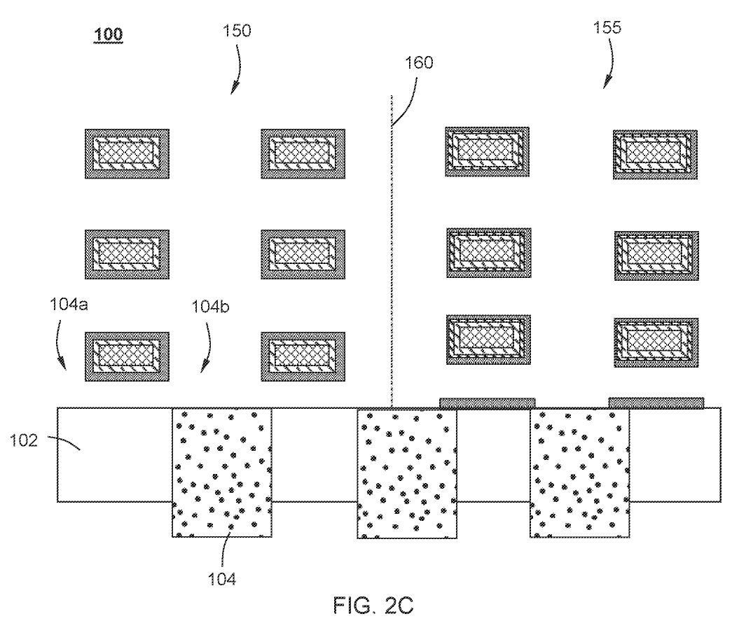

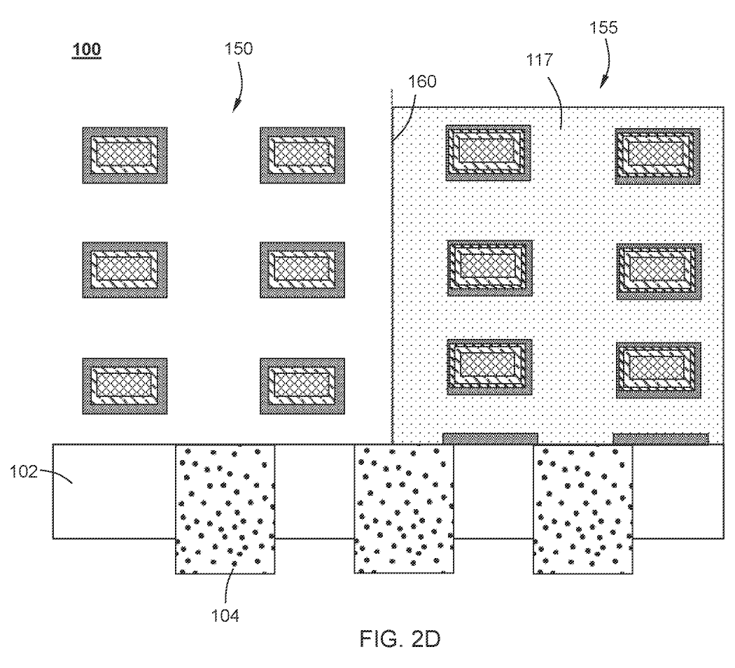

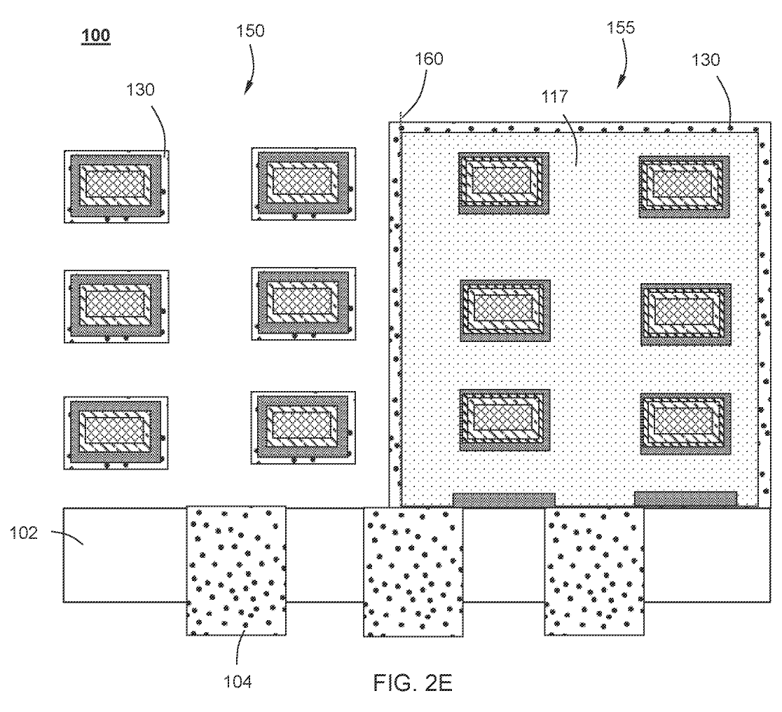

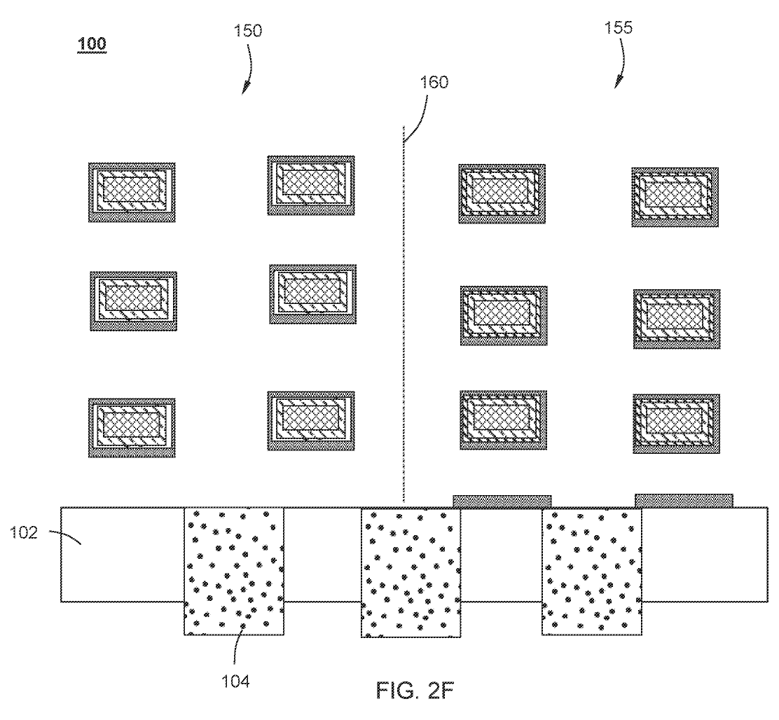

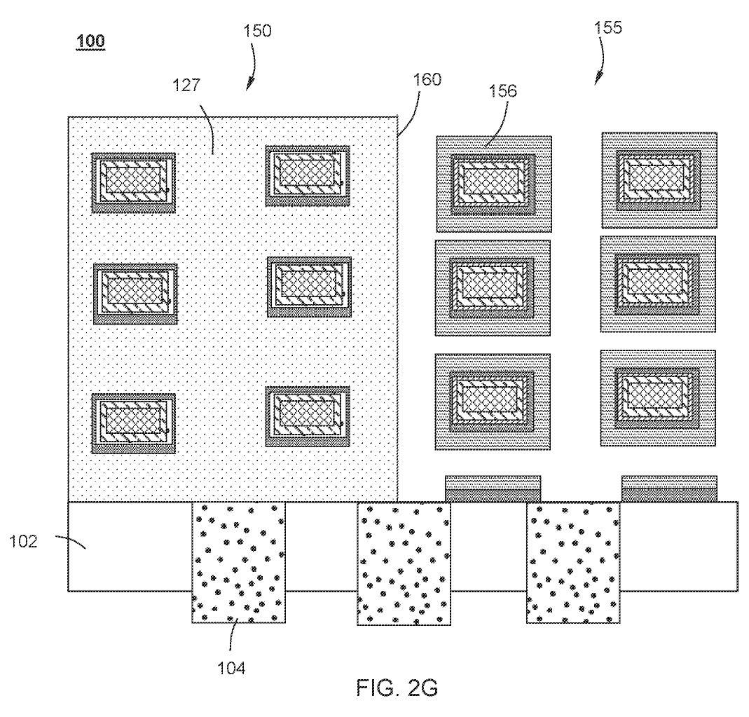

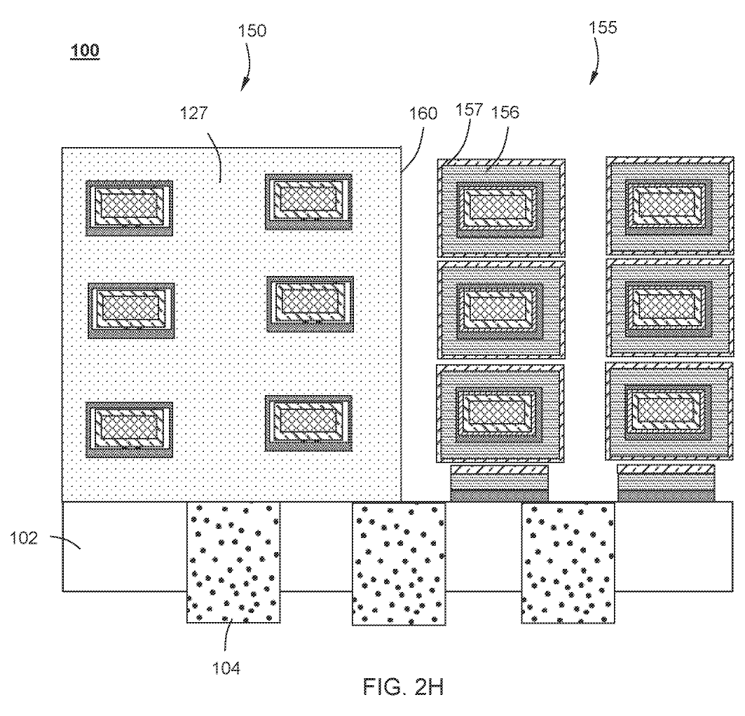

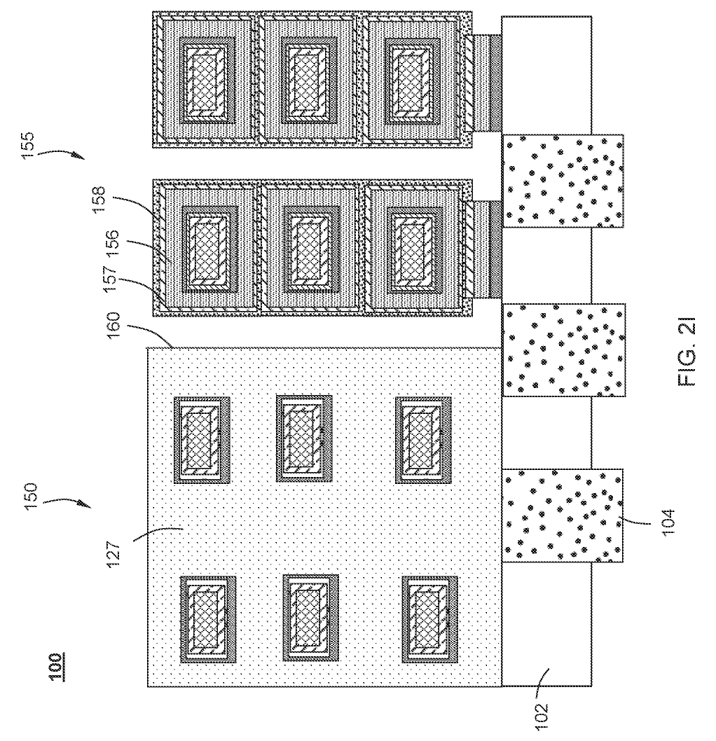

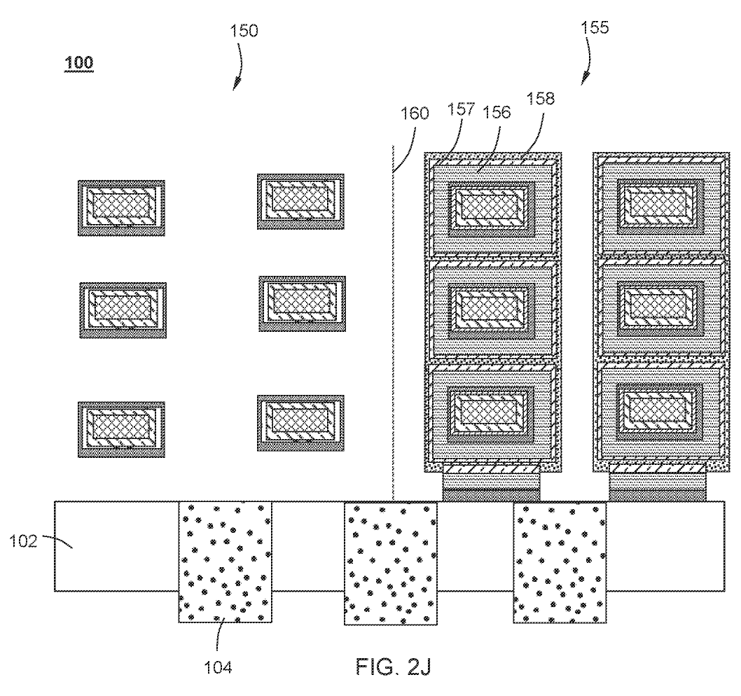

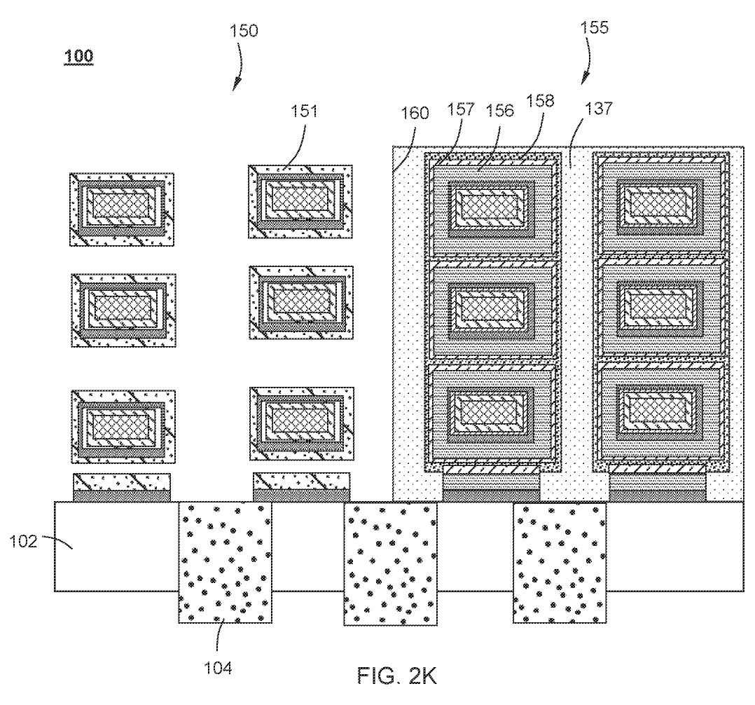

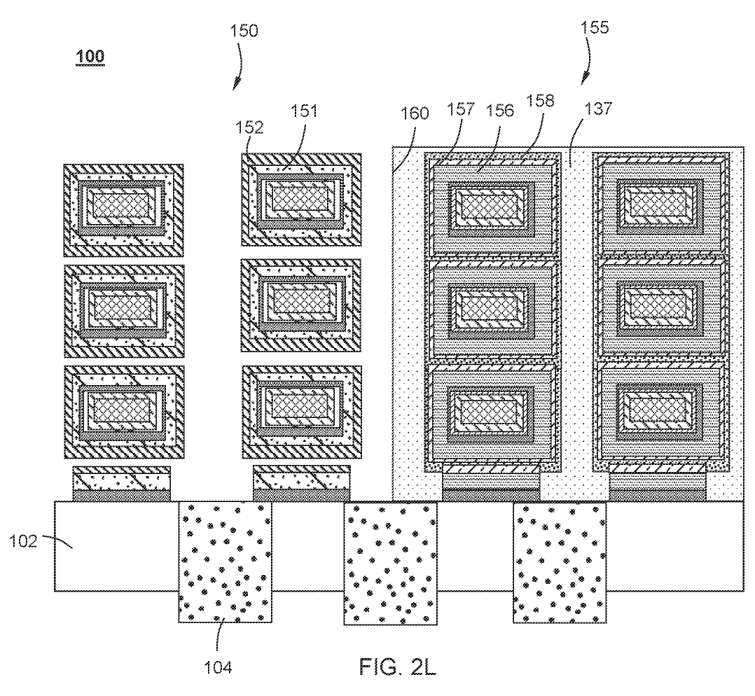

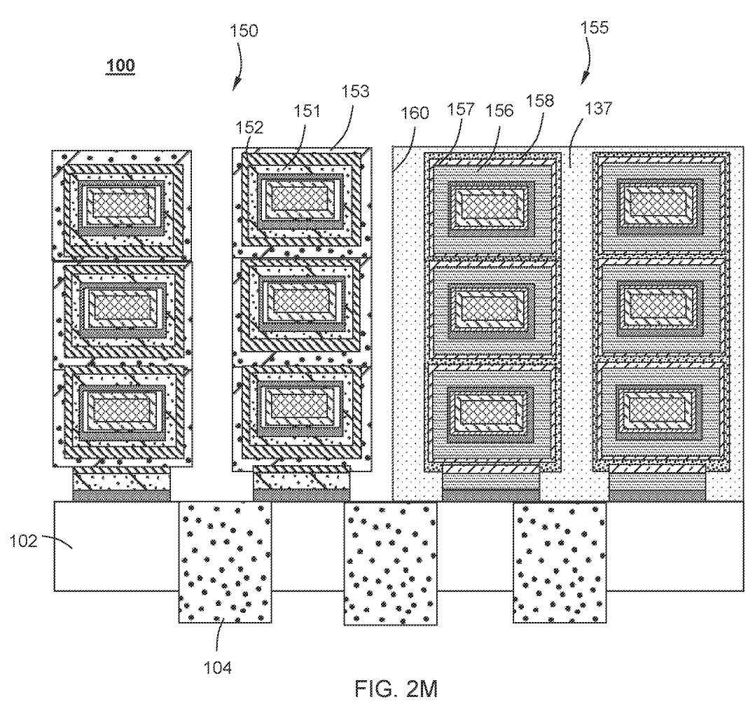

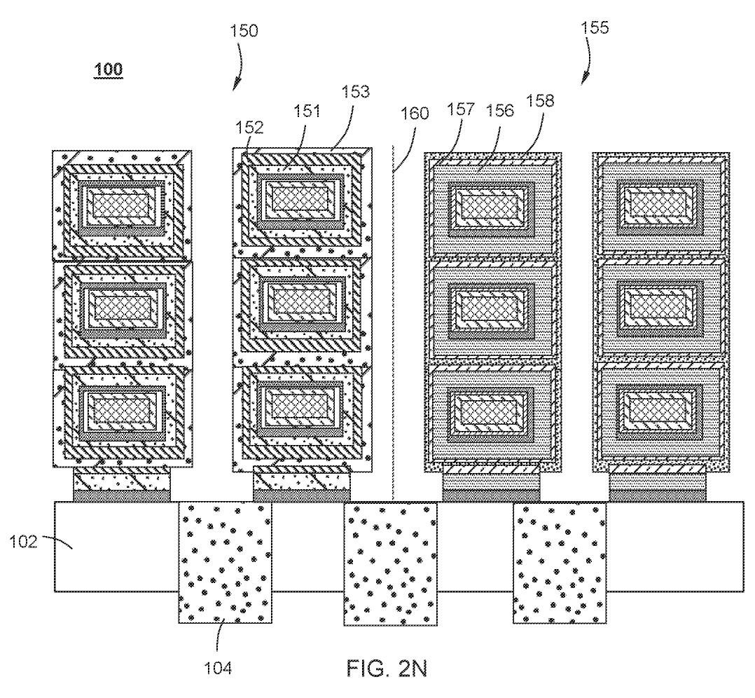

FIGS. 2A–2N illustrate a cross-sectional view of a substrate 102 according to one or more embodiments of the disclosure. FIGS. 2B–2N illustrate a cross-sectional view of a P-metal stack 155 and an N-metal stack 150 on the substrate 102. The substrate 102 illustrated in FIGS. 2A–2N can be processed by the methods described herein, e.g., the method 10, the method 20, and/or the method 30.

Referring to FIGS. 1A–1C and 2A–2N, a semiconductor device 100 (e.g., an electronic device), includes the substrate 102. The substrate 102 can include any suitable substrate material. In one or more embodiments, the substrate 102 comprises a semiconductor material, e.g., silicon (Si), carbon (C), germanium (Ge), silicon germanium (SiGe), gallium arsenide (GaAs), indium phosphate (InP), indium gallium arsenide (InGaAs), indium aluminum arsenide (InAlAs), germanium (Ge), silicon germanium (SiGe), other semiconductor materials, or any combination thereof. In one or more embodiments, the substrate 102 comprises one or more of silicon (Si), germanium (Ge), gallium (Ga), arsenic (As), indium (In), phosphorus (P), or selenium (Se). Although a few examples of materials from which the substrate 102 may be formed are described herein, any material that may serve as a foundation upon which passive and active electronic devices (e.g., transistors, memories, capacitors, inductors, resistors, switches, integrated circuits, amplifiers, optoelectronic devices, or any other electronic devices) may be built falls within the spirit and scope of the disclosure.

In FIGS. 2A–2N, the substrate 102 includes a plurality of shallow trench isolation (STI) regions 104. In one or more embodiments, each of the plurality of STI regions 104 are independently filled with an oxide material. The oxide material can be any suitable oxygen-containing material. In one or more embodiments the oxide material is silicon oxide. In one or more embodiments, each of the plurality of STI regions 104 are disposed within the substrate 102. The substrate 102 has a top surface 103. In one or more embodiments, each of the plurality of STI regions 104 are disposed within the substrate 102 and extend up to the top surface 103.

A first sacrificial layer 107 is shown on the top surface 103 of the substrate 102. The first sacrificial layer 107 can comprise any suitable material. In one or more embodiments, the first sacrificial layer 107 comprises aluminum oxide (Al₂O₃), silicon oxynitride (SiON), silicon nitride (SiN), boron nitride (BN), or boron-doped silicon nitride. In one or more embodiments, the first sacrificial layer 107 has a protective layer 110 thereon. The protective layer 110 can comprise any suitable material. In one or more embodiments, the protective layer 110 comprises a photoresist material.

In one or more embodiments, the substrate 102 is a p-type or n-type substrate. As used herein, the term "n-type" refers to semiconductors that are created by doping an intrinsic semiconductor with an electron donor element during manufacture. The term n-type comes from the negative charge of the electron. In n-type semiconductors, electrons are the majority carriers and holes are the minority carriers. As used herein, the term "p-type" refers to the positive charge of a well (or hole). As opposed to n-type semiconductors, p-type semiconductors have a larger hole concentration than electron concentration. In p-type semiconductors, holes are the majority carriers and electrons are the minority carriers.

Referring to FIGS. 2B–2N, the P-metal stack 155 and the N-metal stack 150 are shown. In one or more embodiments, the protective layer 110 is removed from the substrate 102. In one or more embodiments, a portion of the first sacrificial layer 107 is removed from the substrate 102. In one or more embodiments, the first sacrificial layer 107 is selectively removed from the P-metal stack 155. In embodiments where the first sacrificial layer 107 is selectively removed from the P-metal stack 155, the first sacrificial layer 107 remains on the N-metal stack 150.

In one or more embodiments, the protective layer 110 and the portion of the first sacrificial layer 107 can independently be removed by an etching process. The etching process can be any suitable etching process known to the skilled artisan. In some embodiments, the etching process comprises a wet etch process or a dry etch process, described further herein.

In FIGS. 2B–2N, a dashed line 160 is shown in phantom to distinguish the P-metal stack 155 from the N-metal stack 150 in the cross-sectional view of the substrate 102.

Each of the P-metal stack 155 and the N-metal stack 150 are formed on a channel 105 located between a source region 104a and a drain region 104b on the substrate 102.

The source region 104a is on the top surface 103 of the substrate 102. In one or more unillustrated embodiments, the source region 104a has a source and a source contact. The drain region 104b is on the top surface 103 of the substrate 102 opposite the source region 104a. In one or more unillustrated embodiments, the drain region 104b has a drain and a drain contact.

In one or more embodiments, the source region 104a and/or the drain region 104b can be any suitable material known to the skilled artisan. In one or more embodiments, the source region 104a and/or the drain region 104b may have more than one layer. For example, the source region 104a and/or the drain region 104b may independently comprise three layers. In one or more embodiments, the source region 104a and the drain region 104b may independently comprise one or more of copper (Cu), cobalt (Co), tungsten (W), titanium (Ti), molybdenum (Mo), nickel (Ni), ruthenium (Ru), silver (Ag), gold (Au), iridium (Ir), platinum (Pt), phosphorus (P), germanium (Ge), silicon (Si), aluminum (Al), or zirconium (Zr). In some embodiments, the source region 104a and the drain region 104b may independently comprise a bottom layer of silicon with doped epi (e.g., SiGe, SiP, and the like), a second layer of a metal silicide or a rare metal silicide, for example, to form an ohmic contact, and a third, or top, layer which may be a metal such as, but not limited to, cobalt, tungsten, ruthenium, and the like. In some embodiments, the source region 104a and the drain region 104b may be raised source/drain regions formed by an epitaxial layer deposition process.

In one or more embodiments, the source contact and/or the drain contact may independently be selected from one or more of nitrogen (N), copper (Cu), cobalt (Co), tungsten (W), titanium (Ti), molybdenum (Mo), nickel (Ni), ruthenium (Ru), silver (Ag), gold (Au), iridium (Ir), tantalum (Ta), or platinum (Pt). In one or more embodiments, the source contact and/or the drain contact are deposited by any suitable process known to the skilled artisan, including, but not limited to ALD, CVD, PVD, MBE, MOCVD, spin-on, or other insulating layer deposition techniques known to the skilled artisan.

In one or more embodiments, the channel 105 comprises silicon (Si). In one or more embodiments, the channel 105 comprises silicon germanium (SiGe).

Some embodiments advantageously provide multi-Vₜ integration schemes that can be achieved in the scaled space between one or more nanosheets. In one or more embodiments, the channel 105 of the P-metal stack 155 and the N-metal stack 150 defines a plurality of nanosheet channel layers. The plurality of nanosheet channel layers include a space between each nanosheet channel layer.

Each of the P-metal stack 155 and the N-metal stack 150 independently comprise an interfacial layer 106 on the channel 105 and a high-ĸ dielectric layer 108 on the interfacial layer 106. The first sacrificial layer 107 remaining on the N-metal stack 150 in FIG. 2B is configured to prevent deposition on the channel 105, the interfacial layer 106, and the high-ĸ dielectric layer 108 of the N-metal stack 150.

Referring to operation 11 of the method 10, operation 21 of the method 20, and operation 31 of the method 30, the interfacial layer 106 may be deposited on the channel 105 by a deposition technique, such as, but not limited to, ALD, CVD, PVD, MBE, MOCVD, spin-on, or other insulating layer deposition techniques known to the skilled artisan.

The interfacial layer 106 can have any suitable thickness. In one or more embodiments, the interfacial layer 106 has a thickness in a range of 3 Å to 10 Å. In one or more embodiments, the interfacial layer 106 encapsulates the channel 105.

In some embodiments, the interfacial layer 106 comprises a dielectric material selected from one or more of silicon (Si), silicon oxide (SiOx), hydrogenated silicon oxide, doped silicon, doped silicon oxide, or spin-on dielectrics. In one or more embodiments, the interfacial layer 106 comprises a silicon oxide (SiOx) layer formed on doped silicon or undoped silicon. In one or more embodiments, the interfacial layer 106 may be formed by etching and an oxide forming on the surface.

In some embodiments, a wet chemistry technique is performed to form the interfacial layer 106. The wet chemistry technique may be any suitable technique known to the skilled artisan. In some embodiments, the wet chemistry technique includes a pre-clean process. In some embodiments, the pre-clean process includes using a SC-1 solution comprising one or more of ozone, ammonium hydroxide or hydrogen peroxide. In some embodiments, the pre-clean process includes using a SC-1 solution without ozone, ammonium hydroxide or hydrogen peroxide. In some embodiments, after using the SC-1 solution, the pre-clean process includes using dilute hydrofluoric acid (dilute HF), including greater than 100:1, such as 130:1 dilute HF, to etch away native oxide on the substrate 102 to form a hydrophobic surface (i.e., the interfacial layer 106).

In some embodiments, a rapid thermal process (RTP) is used to form the interfacial layer 106. The RTP may be any suitable process known to the skilled artisan. In some embodiments, the RTP is a thermal oxidation process in which a silicon oxide (SiOx) layer is grown on the substrate 102.

Referring still to operation 11 of the method 10, operation 21 of the method 20, and operation 31 of the method 30, the high-ĸ dielectric layer 108 is deposited on the interfacial layer 106 using a deposition technique, such as, but not limited to, ALD, CVD, PVD, MBE, MOCVD, spin-on, or other insulating layer deposition techniques known to the skilled artisan. In some embodiments, the high-ĸ dielectric layer 108 is deposited by ALD.

The high-ĸ dielectric layer 108 can have any suitable thickness. In one or more embodiments, the high-ĸ dielectric layer 108 has a thickness in a range of 10 Å to 20 Å. In some embodiments, the high-ĸ dielectric layer 108 encapsulates the interfacial layer 106 on the channel 105.

In some embodiments, the high-ĸ dielectric layer 108 comprises one or more of hafnium oxide (HfOx), zirconium oxide (ZrOx), or hafnium zirconium oxide (HfZrOx). In some embodiments, the high-ĸ dielectric layer 108 comprises hafnium oxide (HfOx).

Referring to operation 32 of the method 30, setting the dipole for the P-metal stack 155 comprises a dipole engineering technique. Any suitable dipole engineering technique can be employed to set the dipole for the P-metal stack 155. In some embodiments, setting the dipole for the P-metal stack 155 at operation 32 of the method 30 comprises: depositing a first n-type dipole layer or a first p-type dipole layer on the P-metal stack; annealing the P-metal stack to drive atoms from the first n-type dipole layer or the first p-type dipole layer into an interface between the high-ĸ dielectric layer and the interfacial layer; and removing the first n-type dipole layer or the first p-type dipole layer.

Referring to FIG. 2B, operation 32 of the method 30 comprises depositing a first n-type dipole layer or a first p-type dipole layer on the P-metal stack 155. As used herein, dipole layer 120 refers to the first n-type dipole layer or the first p-type dipole layer. In FIG. 2B, the dipole layer 120 is also deposited on the first sacrificial layer 107 covering the N-metal stack 150.

The dipole layer 120 (e.g., the first n-type dipole layer or the first p-type dipole layer) can be deposited using a deposition technique, such as, but not limited to, ALD, CVD, PVD, MBE, MOCVD, spin-on, radical-assisted doping, or other insulating layer deposition techniques known to the skilled artisan.

In one or more embodiments, the first n-type dipole layer comprises one or more of lanthanum (La), strontium (Sr), scandium (Sc), yttrium (Y), zirconium (Zr), ytterbium (Yb), or barium (Ba). In one or more embodiments, the first n-type dipole layer comprises lanthanum nitride (LaN).

In one or more embodiments, the first p-type dipole layer comprises one or more of aluminum (Al), zinc (Zn), gallium (Ga), indium (In), tin (Sn), antimony (Sb), tellurium (Te), niobium (Nb), molybdenum (Mo), tantalum (Ta), tungsten (W), germanium (Ge), bismuth (Bi), selenium (Se), carbides thereof, or nitrides thereof. In one or more embodiments, the first p-type dipole layer comprises aluminum nitride (AlN).

The dipole layer 120 may be deposited as a single layer or as a multilayer film. The dipole layer 120 may be deposited to a predetermined thickness.

In one or more embodiments, the dipole layer 120 is deposited by atomic layer deposition (ALD) at a temperature in the range of about 200 ° C. to about 600 ° C. In one or more embodiments, the dipole layer 120 is deposited by atomic layer deposition (ALD) at a temperature less than or equal to about 450 ° C. In one or more embodiments, the dipole layer 120 has a thickness in a range of 3 Å to 20 Å. In one or more specific embodiments, the dipole layer 120 has a thickness in a range of 10 Å to 20 Å.

Referring to FIG. 2C, operation 32 of the method 30 comprises annealing the P-metal stack 155 to drive atoms from the first n-type dipole layer or the first p-type dipole layer into an interface between the high-ĸ dielectric layer 108 and the interfacial layer 106; and removing the first n-type dipole layer or the first p-type dipole layer.

In one or more embodiments, annealing the P-metal stack 155 is performed at a temperature of less than or equal to 1150 ° C. to drive in metal atoms from the dipole layer 120 into an interface between the high-ĸ dielectric layer 108 and the interfacial layer 106. In some embodiments, annealing the P-metal stack 155 is performed at a temperature of less than or equal to 950 ° C. In some embodiments, the temperature is in a range of from 500 ° C. to 1150 ° C., such as in a range of from 700 ° C. to 950 ° C.

Without intending to be bound by theory, it is thought that annealing the P-metal stack 155 drives an increased number of atoms from the dipole layer 120 into the interface of the interfacial layer 106 and the high-ĸ dielectric layer 108, as compared to methods where annealing does not occur. In one or more embodiments, annealing the P-metal stack 155 includes a rapid thermal process (RTP), such as an in situ RTP. As used in this context, the “in situ RTP” is performed without a vacuum break. The RTP may be any suitable process known to the skilled artisan. In one or more embodiments, the RTP includes one or more of a spike anneal process, a nanosecond anneal process, or a millisecond anneal process.

In one or more embodiments, the spike anneal process includes exposing the substrate at a temperature of less than or equal to 950 ° C. in a nitrogen (N₂) ambient environment for 15 seconds. In one or more embodiments, the spike anneal process is performed at a temperature in a range of from 700 ° C. to 950 ° C. The RTP may include a nanosecond anneal process (flash anneal process) or a millisecond anneal process (laser anneal process), as will be understood by the skilled artisan. In one or more embodiments, the nanosecond anneal process and the millisecond anneal process are independently performed at a temperature less than or equal to 1150 ° C.

Without intending to be bound by theory, the RTP is believed to densify and improve the physical properties of the deposited dipole layer 120 without damaging the high-ĸ dielectric layer 108. Without intending to be bound by theory, when the P-metal stack 155 is annealed at a temperature of less than or equal to 1150 ° C. to drive atoms from the dipole layer 120 into the interface of the interfacial layer 106 and the high-ĸ dielectric layer 108, the interface of the interfacial layer 106 and the high-ĸ dielectric layer 108 comprises properties of the dipole layer 120. In FIG. 2C, a portion of the high-ĸ dielectric layer 108 is shown as surrounding the dipole layer 120 to illustrate annealing and the driving in of atoms from the dipole layer 120.

Without intending to be bound by theory, it is thought that setting the dipole as described above, simplifies the existing integration flow, reducing the integration costs. Additionally, when atoms (such as metal atoms) from the dipole layer 120 are embedded in the interfacial layer 106 and/or the high-ĸ dielectric layer 108, such as by annealing using an in situ RTP process, the dipole is set and it is thought that oxidation of the dipole layer 120 can be reduced or eliminated.

After driving in atoms from the dipole layer 120 into the interface of the interfacial layer 106 and the high-ĸ dielectric layer 108, any remaining thickness of the dipole layer 120 is removed from the top of the high-ĸ dielectric layer 108, in accordance with operation 32 of the method 30. The dipole layer 120 can be removed by any suitable etching process, including, but not limited to, the etching processes described herein.

Once the atoms from the dipole layer 120 have been driven into the interface of the interfacial layer 106 and the high-ĸ dielectric layer 108, and any remaining thickness of the dipole layer 120 has been removed from the top of the high-ĸ dielectric layer 108, the dipole has been set for the P-metal stack 155 and operation 32 of the method 30 has been completed.

The dipole layer 120 is also removed from the first sacrificial layer 107 on the N-metal stack 150. In FIG. 2C, the first sacrificial layer 107 is removed and the source region 104a and the drain region 104b of the N-metal stack 150 are shown.

The dipole layer 120 and the first sacrificial layer 107 can each be independently removed by an etching process. In some embodiments, the dipole layer 120 and the first sacrificial layer 107 are removed by the same etching process.

The etching process can be any suitable etching process known to the skilled artisan. In some embodiments, the etching process comprises a wet etch process or a dry etch process. In some embodiments, the etching process comprises a wet etch process. In some embodiments, the wet etch process includes a pre-clean process. In some embodiments, the pre-clean process includes using one or more of ammonium hydroxide (NH₄OH) or water (H₂O). In some embodiments, the water (H₂O) is de-ionized water (DI). In some embodiments, the pre-clean process includes using a ratio of DI:NH₄OH in a range of from 100:1 DI:NH₄OH to 5:1 DI:NH₄OH.

In some embodiments, the pre-clean process includes using a SC-1 solution or a SC-2 solution. In one or more embodiments, the SC-1 solution comprises one or more of ozone, ammonium hydroxide or hydrogen peroxide. In one or more embodiments, the SC-2 solution comprises one or more of hydrochloric aid or hydrogen peroxide. It has advantageously been found that using a SC-1 solution or a SC-2 solution selectively etches the deposited dipole layer 120 and the first sacrificial layer 107 without etching a portion of the interfacial layer 106 and/or the high-ĸ dielectric layer 108.

For example, if the work-function was shifted in either P-dipole or N-dipole bandedge after dipole engineering, the methods herein can be used to achieve the desired transistor Vₜ, such as ultra-low Vₜ (ULVₜ), low Vₜ (LVₜ), standard Vₜ (SVₜ), or the mid-gap: high Vₜ (HVₜ), using a combination of P-dipole and P-metal and N-dipole and N-metal. For example, methods described herein can shift the Vₜ from ULVₜ, which is the most P-dipole and/or N-dipole bandedge, respectively, to LVₜ or SVₜ, or the mid-gap: HVₜ. In some embodiments, ULVₜ can be achieved by using a P-dipole and a P-metal in the P-metal stack 155 and an N-dipole and an N-metal in N-metal stack 150.

In some embodiments, LVₜ can be achieved by using a P-metal or a P-dipole (thinner dipole layer) and a P-metal in the P-metal stack 155 and an N-metal or an N-dipole (thinner dipole layer) and an N-metal in the N-metal stack 150. In some embodiments, SVₜ can be achieved by using a thin P-metal layer in the P-metal stack 155 or a thin N-metal layer in the N-metal stack 150, using a combination of P-dipole and N-dipole of a predetermined thicknesses. In some embodiments, HVₜ can be achieved by a combination of P-metal and N-metal or a mid-gap work-function metal. In some embodiments, the mid-gap work-function metal includes any suitable metal material having a work-function from 4.4 to 4.6 eV. It has advantageously been found that, depending on the metal precursor that is chosen, the methods described herein can either decrease or increase the effective work function (eWF) of the film stack (e.g., the P-metal stack 155 and/or the N-metal stack 150). Thus, tuning of eWF can be done by using different mid-gap work-function metals. The mid-gap work-function metal can be chosen based on tuning the multi-Vₜ requirements.

In one or more embodiments, in FIG. 2D, a second sacrificial layer 117 is selectively deposited on the P-metal stack 155. The second sacrificial layer 117 can comprise any suitable material. In one or more embodiments, the second sacrificial layer 117 comprises aluminum oxide (Al₂O₃), silicon oxynitride (SiON), silicon nitride (SiN), boron nitride (BN), or boron-doped silicon nitride. In one or more embodiments, the first sacrificial layer 107 and the second sacrificial layer 117 are the same. The second sacrificial layer 117 on the P-metal stack 155 in FIG. 2D is configured to prevent deposition thereon.

Referring to operation 33 of the method 30, setting the dipole for the N-metal stack 150 comprises a dipole engineering technique. Any suitable dipole engineering technique can be employed to set the dipole for the N-metal stack 150. In one or more embodiments, the same dipole engineering technique is used to set the dipole for the P-metal stack 155 and the N-metal stack 150, respectively. In one or more embodiments, different dipole engineering techniques are used to set the dipole for the P-metal stack 155 and the N-metal stack 150, respectively.

In some embodiments, setting the dipole for the N-metal stack 150 at operation 33 of the method 30 comprises: depositing a second n-type dipole layer or a second p-type dipole layer on the N-metal stack; annealing the N-metal stack to drive atoms from the second n-type dipole layer or the second p-type dipole layer into an interface between the high-ĸ dielectric layer and the interfacial layer; and removing the second n-type dipole layer or the second p-type dipole layer.

Referring to FIG. 2E, operation 33 of the method 30 comprises depositing a second n-type dipole layer or a second p-type dipole layer on the N-metal stack 150. As used herein, dipole layer 130 refers to the second n-type dipole layer or the second p-type dipole layer. In FIG. 2E, the dipole layer 130 is also deposited on the second sacrificial layer 117 covering the P-metal stack 155.

The dipole layer 130 (e.g., the second n-type dipole layer or the second p-type dipole layer) can be deposited using a deposition technique, such as, but not limited to, ALD, CVD, PVD, MBE, MOCVD, spin-on, radical-assisted doping, or other insulating layer deposition techniques known to the skilled artisan.

In one or more embodiments, the second n-type dipole layer comprises one or more of (La), strontium (Sr), scandium (Sc), yttrium (Y), zirconium (Zr), ytterbium (Yb), or barium (Ba). In one or more embodiments, the second n-type dipole layer comprises lanthanum nitride (LaN).

In one or more embodiments, the second p-type dipole layer comprises one or more of aluminum (Al), zinc (Zn), gallium (Ga), indium (In), tin (Sn), antimony (Sb), tellurium (Te), niobium (Nb), molybdenum (Mo), tantalum (Ta), tungsten (W), germanium (Ge), bismuth (Bi), selenium (Se), carbides thereof, or nitrides thereof. In one or more embodiments, the second p-type dipole layer comprises aluminum nitride (AlN).

The dipole layer 130 may be deposited as a single layer or as a multilayer film. The dipole layer 130 may be deposited to a predetermined thickness.

In one or more embodiments, the dipole layer 130 is deposited by atomic layer deposition (ALD) at a temperature in the range of about 200 ° C. to about 600 ° C. In one or more embodiments, the dipole layer 130 is deposited by atomic layer deposition (ALD) at a temperature less than or equal to about 450 ° C. In one or more embodiments, the dipole layer 130 has a thickness in a range of 3 Å to 20 Å. In one or more specific embodiments, the dipole layer 130 has a thickness in a range of 10 Å to 20 Å.

Referring to FIG. 2F, operation 33 of the method 30 comprises annealing the N-metal stack 150 to drive atoms from the second n-type dipole layer or the second p-type dipole layer into an interface between the high-ĸ dielectric layer 108 and the interfacial layer 106; and removing the second n-type dipole layer or the second p-type dipole layer.

In one or more embodiments, annealing the N-metal stack 150 is performed at a temperature of less than or equal to 1000 ° C. to drive in metal atoms from the dipole layer 130 into an interface between the high-ĸ dielectric layer 108 and the interfacial layer 106. In some embodiments, annealing the N-metal stack 150 is performed at a temperature of less than or equal to 950 ° C. In some embodiments, the temperature is in a range of from 500 ° C. to 1150 ° C., such as in a range of from 700 ° C. to 950 ° C.

Without intending to be bound by theory, it is thought that annealing the N-metal stack 150 drives an increased number of atoms from the dipole layer 130 into the interface of the interfacial layer 106 and the high-ĸ dielectric layer 108, as compared to methods where annealing does not occur. In one or more embodiments, annealing the N-metal stack 150 includes a rapid thermal process (RTP), such as an in situ RTP. As used in this context, the “in situ RTP” is performed without a vacuum break. The RTP may be any suitable process known to the skilled artisan. In one or more embodiments, the RTP includes one or more of a spike anneal process, a nanosecond anneal process, or a millisecond anneal process.

Without intending to be bound by theory, the RTP is believed to densify and improve the physical properties of the deposited dipole layer 130. Without intending to be bound by theory, when the N-metal stack 150 is annealed at a temperature of less than or equal to 1150 ° C. to drive atoms from the dipole layer 130 into the interface of the interfacial layer 106 and the high-ĸ dielectric layer 108, the interface of the interfacial layer 106 and the high-ĸ dielectric layer 108 comprises properties of the dipole layer 130.

In FIG. 2F, a portion of the high-ĸ dielectric layer 108 is shown as surrounding the dipole layer 130 to illustrate annealing and the driving in of atoms from the dipole layer 130.

Without intending to be bound by theory, it is thought that setting the dipole as described above, simplifies the existing integration flow, reducing the integration costs. Additionally, when atoms (such as metal atoms) from the dipole layer 130 are embedded in the interfacial layer 106 and/or the high-ĸ dielectric layer 108, such as by annealing using an in situ RTP process, the dipole is set and it is thought that oxidation of the dipole layer 130 can be reduced or eliminated.

In some embodiments, annealing the P-metal stack 155 and the N-metal stack 150 comprises a single in situ rapid thermal process (RTP). Advantageously, it has been found that annealing once during the methods described herein to drive in atoms from the dipole layer 120 and the dipole layer 130, i.e., the single in situ RTP, is configured to minimize degradation of the high-ĸ dielectric layer 108. Stated differently, in one or more embodiments, the dipole layer 120 (i.e., the first n-type dipole layer or the first p-type dipole layer) and the dipole layer 130 (i.e., the second n-type dipole layer or the second p-type dipole layer) are each deposited, then annealing the P-metal stack 155 and the N-metal stack 150 comprises the single in situ RTP.

After driving in atoms from the dipole layer 130 into the interface of the interfacial layer 106 and the high-ĸ dielectric layer 108, any remaining thickness of the dipole layer 130 is removed from the top of the high-ĸ dielectric layer 108, in accordance with operation 33 of the method 30. The dipole layer 130 can be removed by any suitable etching process, including, but not limited to, the etching processes described herein.

Once the atoms from the dipole layer 130 have been driven into the interface of the interfacial layer 106 and the high-ĸ dielectric layer 108, and any remaining thickness of the dipole layer 130 has been removed from the top of the high-ĸ dielectric layer 108, the dipole has been set for the N-metal stack 150 and operation 33 of the method 30 has been completed.

The dipole layer 130 is also removed from the second sacrificial layer 117 on the P-metal stack 155. The dipole layer 120 and the first sacrificial layer 107 can each be independently removed by an etching process. In some embodiments, the dipole layer 130 and the second sacrificial layer 117 are removed by the same etching process. In some embodiments, the dipole layer 130 and the second sacrificial layer 117 are removed by the same etching process by which the dipole layer 120 and the first sacrificial layer 107 are removed.

Referring to FIG. 2G, a third sacrificial layer 127 is formed on the N-metal stack 150 and at least one P-metal gate film is deposited on the P-metal stack 155. The at least one P-metal gate film can include any suitable number of P-metal gate films.

Each of the at least one P-metal gate films can independently be deposited using a deposition technique, such as, but not limited to, ALD, CVD, PVD, MBE, MOCVD, spin-on, radical-assisted doping, or other insulating layer deposition techniques known to the skilled artisan. Each of the at least one P-metal gate films can independently have any suitable thickness. In some embodiments, each of the at least one P-metal gate films independently has a thickness in a range of from greater than or equal to 1 nm to less than or equal to 3 nm. Advantageously, the at least one P-metal gate films are configured to be deposited in the scaled space between one or more nanosheets.

Each of the at least one P-metal gate films independently include one or more of: a tunable thickness configured to provide multiple threshold voltages (multi-Vₜ), or tunable composition, i.e., a binary metal nitride film or a ternary metal nitride film configured to provide multiple threshold voltages (multi-Vₜ).

In accordance with operation 12 of the method 10 and operation 35 of the method 30, at least one P-metal gate film is deposited on the P-metal stack 155. A first P-metal gate film 156 is shown in FIG. 2G. In one or more embodiments, the first P-metal gate film 156 has a tunable thickness configured to provide multiple threshold voltages (multi-Vₜ). In one or more embodiments, the first P-metal gate film 156 comprises a tunable composition, i.e., a binary metal nitride film or a ternary metal nitride film configured to provide multiple threshold voltages (multi-Vₜ). In one or more embodiments, the first P-metal gate film 156 has a tunable thickness configured to provide multiple threshold voltages (multi-Vₜ), and comprises a tunable composition, i.e., a binary metal nitride film or a ternary metal nitride film configured to provide multiple threshold voltages (multi-Vₜ).

The thickness of the at least one P-metal gate film can be increased to reach the desired Vₜ by performing a dipole engineering process. In one or more embodiments, the dipole engineering process includes depositing a metal into the at least one P-metal gate film to reach the desired Vₜ. Advantageously, the thickness of the at least one P-metal gate film can be increased to reach the desired Vₜ without having to perform a patterning/annealing/removal step, which is typically done with dipole density tuning at the interfacial layer/high-ĸ dielectric layer interface.

In one or more embodiments, the first P-metal gate film 156 has a formula of MXN, where M is a first metal selected from the group consisting of hafnium (Hf), magnesium (Mg), lanthanum (La), yttrium (Y), aluminum (Al), manganese (Mn), zirconium (Zr), tantalum (Ta), vanadium (V), zinc (Zn), titanium (Ti), niobium (Nb), tin (Sn), tungsten (W), molybdenum (Mo), ruthenium (Ru), and antimony (Sb), X is a second metal selected from the group consisting of hafnium (Hf), magnesium (Mg), lanthanum (La), yttrium (Y), aluminum (Al), manganese (Mn), zirconium (Zr), tantalum (Ta), vanadium (V), zinc (Zn), titanium (Ti), niobium (Nb), tin (Sn), tungsten (W), molybdenum (Mo), ruthenium (Ru), and antimony (Sb), the second metal is different from the first metal, and N is nitrogen.

The first metal M and the second metal X can be present in the formula of MXN in any suitable amount in at.%. In some embodiments, X is in a range of from 0 at.% to 40 at.%.

In specific embodiments where the first P-metal gate film 156 has the formula of MXN, M is titanium (Ti), X is niobium (Nb), and N is nitrogen. In specific embodiments where the first P-metal gate film 156 has the formula of MXN, M is titanium (Ti), X is tantalum (Ta), and N is nitrogen. In specific embodiments where the first P-metal gate film 156 has the formula of MXN, M is titanium (Ti), X is zirconium (Zr), and N is nitrogen. In specific embodiments where the first P-metal gate film 156 has the formula of MXN, M is titanium (Ti), X is hafnium (Hf), and N is nitrogen.

In one or more embodiments, the amount in at.% of the second metal X in the first P-metal gate film 156 can be tuned by the processing conditions and/or process flow used to form the first P-metal gate film 156. It has been advantageously found that the amount in at.% of the second metal X in the first P-metal gate film 156 can be tuned by deposition temperature.

Without intending to be bound by theory, it has been found that many metal-organic precursors decompose at higher temperatures, such as greater than or equal to 250 ° C. It has been advantageously found that the amount of metal in at.%, such as the first metal M and/or the second metal X, for example, can be increased by increasing deposition temperature.

It has been advantageously found that the amount in at.% of the second metal X in the first P-metal gate film 156 can be tuned by the process flow used to form the first P-metal gate film 156. In specific embodiments, the process flow used to form the first P-metal gate film 156 comprises a first cycle and a second cycle. The first cycle and the second cycle collectively define a looped cycle.

In one or more embodiments, the first cycle includes exposing the substrate 102 to the first metal M, purging, exposing the substrate to nitrogen, and purging.

In one or more embodiments, the second cycle includes exposing the substrate 102 to the second metal X, purging, exposing the substrate to nitrogen, and purging.

The first cycle can be repeated any suitable number of times. The second cycle can be repeated any suitable number of times. The looped cycle can be repeated any suitable number of times.

The thickness of the first P-metal gate film 156 can be tuned by the amount of times the looped cycle is performed. The amount in at.% of the second metal X in the first P-metal gate film 156 can be tuned by altering the ratio of the first cycle to the second cycle. In some embodiments, the ratio of the first cycle to the second cycle is configured to provide X in a range of from 0 at.% to 40 at.% in the first P-metal gate film 156. In one or more embodiments, the first P-metal gate film 156 is configured to provide a first threshold voltage (i.e., a first Vₜ).

Referring still to FIG. 2G, the third sacrificial layer 127 may be the same as the first sacrificial layer 107 and/or the second sacrificial layer 117. The third sacrificial layer 127 on the N-metal stack 150 in FIG. 2G is configured to prevent deposition thereon.

In accordance with operation 12 of the method 10 and operation 35 of the method 30, at least one P-metal gate film is deposited on the P-metal stack 155. A second P-metal gate film 157 is deposited on the first P-metal gate film 156 in FIG. 2H. The second P-metal gate film 157 has a tunable thickness configured to provide multiple threshold voltages (multi-Vₜ). In one or more embodiments, the second P-metal gate film 157 comprises a tunable composition, i.e., a binary metal nitride film or a ternary metal nitride film configured to provide multiple threshold voltages (multi-Vₜ). In one or more embodiments, the second P-metal gate film 157 has a tunable thickness configured to provide multiple threshold voltages (multi-Vₜ), and comprises a tunable composition, i.e., a binary metal nitride film or a ternary metal nitride film configured to provide multiple threshold voltages (multi-Vₜ).

In one or more embodiments, the first P-metal gate film 156 and the second P-metal gate film 157 are the same. In one or more embodiments, the first P-metal gate film 156 and the second P-metal gate film 157 are different. In one or more embodiments, the second P-metal gate film 157 is configured to provide a second threshold voltage (i.e., a second Vₜ).

In FIG. 2H, the third sacrificial layer 127 remains on the N-metal stack 150 and is configured to prevent deposition thereon.

In accordance with operation 12 of the method 10 and operation 35 of the method 30, at least one P-metal gate film is deposited on the P-metal stack 155. In FIG. 2I, a third P-metal gate film 158 is deposited on the second P-metal gate film 157 which is deposited on the first P-metal gate film 156.

In one or more embodiments, the third P-metal gate film 158 has a tunable thickness configured to provide multiple threshold voltages (multi-Vₜ). In one or more embodiments, the third P-metal gate film 158 comprises a tunable composition, i.e., a binary metal nitride film or a ternary metal nitride film configured to provide multiple threshold voltages (multi-Vₜ). In one or more embodiments, the third P-metal gate film 158 has a tunable thickness configured to provide multiple threshold voltages (multi-Vₜ), and comprises a tunable composition, i.e., a binary metal nitride film or a ternary metal nitride film configured to provide multiple threshold voltages (multi-Vₜ).

In some embodiments, one or more of the first P-metal gate film 156, the second P-metal gate film 157, and the third P-metal gate film 158 are the same. In some embodiments, each of the first P-metal gate film 156, the second P-metal gate film 157, and the third P-metal gate film 158 are the same. In some embodiments, each of the first P-metal gate film 156, the second P-metal gate film 157, and the third P-metal gate film 158 are different from one another. In one or more embodiments, the third P-metal gate film 158 is configured to provide a third threshold voltage (i.e., a third Vₜ).

In FIG. 2J, the third sacrificial layer 127 is removed from the N-metal stack 150. The P-metal stack 155 includes the first P-metal gate film 156, the second P-metal gate film 157, and the third P-metal gate film 158.

In some embodiments, each of the at least one P-metal gate films independently has a thickness in a range of from greater than or equal to 1 nm to less than or equal to 3 nm. Advantageously, the at least one P-metal gate films are configured to be deposited in the scaled space between one or more nanosheets. In one or more embodiments, the at least one P-metal gate film (e.g., the first P-metal gate film 156, the second P-metal gate film 157, and the third P-metal gate film 158) collectively have a thickness in a range of from greater than or equal to 1 nm to less than or equal to 3 nm and are deposited in the space between each nanosheet channel layer in the P-metal stack 155.

Referring to FIG. 2K, a fourth sacrificial layer 137 is selectively formed on the P-metal stack 155 and at least one N-metal gate film is deposited on the N-metal stack 150. The at least one N-metal gate film can include any suitable number of N-metal gate films.

Each of the at least one N-metal gate films can independently be deposited using a deposition technique, such as, but not limited to, ALD, CVD, PVD, MBE, MOCVD, spin-on, radical-assisted doping, or other insulating layer deposition techniques known to the skilled artisan. Each of the at least one N-metal gate films can independently have any suitable thickness. In some embodiments, each of the at least one N-metal gate films independently has a thickness in a range of from greater than or equal to 1 nm to less than or equal to 3 nm. Advantageously, the at least one N-metal gate films are configured to be deposited in the scaled space between one or more nanosheets.

Each of the at least one N-metal gate films independently include one or more of: a tunable thickness configured to provide multiple threshold voltages (multi-Vₜ), or a tunable composition, i.e., a binary metal nitride film or a ternary metal nitride film configured to provide multiple threshold voltages (multi-Vₜ).

In accordance with operation 22 of the method 20 and operation 36 of the method 30, at least one N-metal gate film is deposited on the N-metal stack 150. A first N-metal gate film 151 is shown in FIG. 2K. In one or more embodiments, the first N-metal gate film 151 has a tunable thickness configured to provide multiple threshold voltages (multi-Vₜ). In one or more embodiments, the first N-metal gate film 151 comprises a tunable composition, i.e., a binary metal carbide film, a binary metal silicide film, a ternary metal carbide film, or a ternary metal silicide film configured to provide multiple threshold voltages (multi-Vₜ). In one or more embodiments, the first N-metal gate film 151 has a tunable thickness configured to provide multiple threshold voltages (multi-Vₜ), and comprises a tunable composition, i.e., a binary metal carbide film, a binary metal silicide film, a ternary metal carbide film, or a ternary metal silicide film configured to provide multiple threshold voltages (multi-Vₜ).

The thickness of the at least one N-metal gate film can be increased to reach the desired Vₜ by performing a dipole engineering process. In one or more embodiments, the dipole engineering process includes depositing a metal into the at least one N-metal gate film to reach the desired Vₜ. Advantageously, the thickness of the at least one N-metal gate film can be increased to reach the desired Vₜ without having to perform a patterning/annealing/removal step, which is typically done with dipole density tuning at the interfacial layer/high-ĸ dielectric layer interface.

In some embodiments, the first N-metal gate film 151 comprises the binary metal carbide film, the binary metal silicide film, the ternary metal carbide film, the ternary metal silicide film, or combinations thereof. In one or more embodiments, the first N-metal gate film 151 comprises titanium (Ti), tantalum (Ta), aluminum (Al), lanthanum (La), zirconium (Zr), scandium (Sc), yttrium (Y), ytterbium (Yb), carbon (C), silicon (Si), or combinations thereof.

In one or more embodiments, the first N-metal gate film 151 comprises titanium silicide (TiSi), tantalum silicide (TaSi), aluminum silicide (AlSi), lanthanum silicide (LaSi), zirconium silicide (ZrSi), yttrium silicide (YSi), ytterbium silicide (YbSi), scandium silicide (ScSi), lanthanum silicide (LaSi), or combinations thereof. In one or more embodiments, the first N-metal gate film 151 comprises titanium carbide (TiC), tantalum carbide (TaC), aluminum carbide (AlC), lanthanum carbide (LaC), zirconium carbide (ZrC), yttrium carbide (YC), ytterbium carbide (YbC), scandium carbide (ScC), lanthanum carbide (LaC), or combinations thereof.

In one or more embodiments, the first N-metal gate film 151 comprises titanium silicide (TiSi), tantalum silicide (TaSi), aluminum silicide (AlSi), lanthanum silicide (LaSi), zirconium silicide (ZrSi), yttrium silicide (YSi), ytterbium silicide (YbSi), scandium silicide (ScSi), lanthanum silicide (LaSi), titanium carbide (TiC), tantalum carbide (TaC), aluminum carbide (AlC), lanthanum carbide (LaC), zirconium carbide (ZrC), yttrium carbide (YC), ytterbium carbide (YbC), scandium carbide (ScC), lanthanum carbide (LaC), or combinations thereof.

In one or more embodiments, the first N-metal gate film 151 comprises titanium aluminum carbide (TiAlC), titanium aluminum silicide (TiAlSi), tantalum aluminum carbide (TaAlC), tantalum aluminum silicide (TaAlSi), zirconium carbide (ZrC), yttrium carbide (YC), ytterbium carbide (YbC), scandium carbide (ScC), lanthanum carbide (LaC), zirconium aluminum silicide (ZrAlSi), yttrium aluminum silicide (YAlSi), ytterbium aluminum silicide (YbAlSi), scandium aluminum silicide (ScAlSi), lanthanum aluminum silicide (LaAlSi), zirconium aluminum carbide (ZrAlC), yttrium aluminum carbide (YAlC), ytterbium aluminum carbide (YbAlC), scandium aluminum carbide (ScAlC), lanthanum aluminum carbide (LaAlC), or combinations thereof.

To avoid silicon scavenging, a thin layer (less than or equal to 6 Å) of metal nitride (such as, for example, titanium nitride (TiN)) may be deposited below the at least one N-metal gate film). Stated differently, the thin layer of metal nitride may be deposited directly on the high-ĸ dielectric layer 108, and the at least one N-metal gate film may be deposited directly on the thin layer of metal nitride.

In one or more embodiments, the composition of the first N-metal gate film 151 can advantageously be tuned by the processing conditions and/or process flow used to form the first N-metal gate film 151. In one or more embodiments, the first N-metal gate film 151 is configured to provide a first threshold voltage (i.e., a first Vₜ).

In specific embodiments, the process flow used to form the first N-metal gate film 151 comprises a first cycle and a second cycle. In some embodiments, the first cycle and the second cycle collectively define a looped cycle.

The first cycle can be repeated any suitable number of times. The second cycle can be repeated any suitable number of times. The looped cycle can be repeated any suitable number of times.

In specific embodiments, the process flow used to form the first N-metal gate film 151 comprises a first cycle, a second cycle, and a third cycle. In some embodiments, the first cycle, the second cycle, and the third collectively define a looped cycle.

The first cycle can be repeated any suitable number of times. The second cycle can be repeated any suitable number of times. The third cycle can be repeated any suitable number of times. The looped cycle can be repeated any suitable number of times.

In specific embodiments where the first N-metal gate film 151 comprises tantalum aluminum carbide (TaAlC), the first cycle comprises exposing the substrate 102 to a tantalum-containing precursor, and purging. Then, the substrate is purged again after the first cycle. In specific embodiments where the first N-metal gate film 151 comprises tantalum aluminum carbide (TaAlC), the second cycle comprises exposing the substrate 102 to an aluminum-containing precursor, and purging. Then, the substrate is purged again after the second cycle.

The thickness of the first N-metal gate film 151 can be tuned by the amount of times the looped cycle is performed. The amount of aluminum (Al) in at.% in the tantalum aluminum carbide (TaAlC) film can be tuned by repeating one or more of the first cycle or the second cycle. The amount of aluminum (Al) in at.% in the tantalum aluminum carbide (TaAlC) film can be tuned by controlling the temperature of the aluminum-containing precursor ampoule. The amount of aluminum (Al) in at.% in the tantalum aluminum carbide (TaAlC) film can be tuned by controlling the length of time in which the tantalum-containing precursor and/or aluminum-containing precursor are pulsed. The amount of aluminum (Al) in at.% in the tantalum aluminum carbide (TaAlC) film can be tuned by controlling the deposition temperature.

Without intending to be bound by theory, it has been found that many metal-organic precursors decompose at higher temperatures, such as greater than or equal to 250 ° C. When an aluminum-containing precursor decomposes, such as at 300 ° C. to 475 ° C. for example, there is an increased amount of aluminum (in at.%) in the film, which favors bandege work-function for the N-metal stack 150. Accordingly, it has been advantageously found that the amount of aluminum in at.%, for example, can be increased by increasing deposition temperature.

In specific embodiments where the first N-metal gate film 151 comprises titanium aluminum carbide (TiAlC), the first cycle comprises exposing the substrate 102 to a titanium-containing precursor, and purging. Then, the substrate is purged again after the first cycle. In specific embodiments where the first N-metal gate film 151 comprises titanium aluminum carbide (TiAlC), the second cycle comprises exposing the substrate 102 to an aluminum-containing precursor, and purging. Then, the substrate is purged again after the second cycle.

The thickness of the first N-metal gate film 151 can be tuned by the amount of times the looped cycle is performed. The amount of aluminum (Al) in at.% in the titanium aluminum carbide (TiAlC) film can be tuned by repeating one or more of the first cycle or the second cycle. The amount of aluminum (Al) in at.% in the titanium aluminum carbide (TiAlC) film can be tuned by controlling the temperature of the aluminum-containing precursor ampoule. The amount of aluminum (Al) in at.% in the titanium aluminum carbide (TiAlC) film can be tuned by controlling the length of time in which the titanium-containing precursor and/or aluminum-containing precursor are pulsed. The amount of aluminum (Al) in at.% in the titanium aluminum carbide (TiAlC) film can be tuned by controlling the deposition temperature.

In specific embodiments where the first N-metal gate film 151 comprises tantalum aluminum silicon carbide (TaAlSiC), the first cycle comprises exposing the substrate 102 to a tantalum-containing precursor, and purging. Then, the substrate is purged again after the first cycle. In specific embodiments where the first N-metal gate film 151 comprises tantalum aluminum silicon carbide (TaAlSiC), the second cycle comprises exposing the substrate 102 to an aluminum-containing precursor, and purging. Then, the substrate is purged again after the second cycle. In specific embodiments where the first N-metal gate film 151 comprises tantalum aluminum silicon carbide (TaAlSiC), the third cycle comprises exposing the substrate 102 to a silicon-containing precursor, and purging.

The thickness of the first N-metal gate film 151 can be tuned by the amount of times the looped cycle is performed. The amount of aluminum (Al) in at.% in the tantalum aluminum silicon carbide (TaAlSiC) film can be tuned by repeating one or more of the first cycle, the second cycle, or the third cycle. The amount of aluminum (Al) in at.% in the tantalum aluminum silicon carbide (TaAlSiC) film can be tuned by controlling the temperature of the aluminum-containing precursor ampoule. The amount of aluminum (Al) in at.% in the tantalum aluminum silicon carbide (TaAlSiC) film can be tuned by controlling the deposition temperature.

In specific embodiments, the first N-metal gate film 151 comprising the tantalum aluminum silicon carbide (TaAlSiC) film has in a range of from 3 at.% to 10 at.% of silicon (Si). It has been advantageously found that in the range of from 3 at.% to 10 at.% of silicon (Si) in the first N-metal gate film 151 comprising the tantalum aluminum silicon carbide (TaAlSiC) film maintains low resistivity and high electrical conductivity.

In specific embodiments where the first N-metal gate film 151 comprises titanium aluminum silicon carbide (TiAlSiC), the first cycle comprises exposing the substrate 102 to a titanium-containing precursor, and purging. Then, the substrate is purged again after the first cycle. In specific embodiments where the first N-metal gate film 151 comprises titanium aluminum silicon carbide (TiAlSiC), the second cycle comprises exposing the substrate 102 to an aluminum-containing precursor, and purging. Then, the substrate is purged again after the second cycle. In specific embodiments where the first N-metal gate film 151 comprises titanium aluminum silicon carbide (TiAlSiC), the third cycle comprises exposing the substrate 102 to a silicon-containing precursor, and purging.

The thickness of the first N-metal gate film 151 can be tuned by the amount of times the looped cycle is performed. The amount of aluminum (Al) in at.% in the titanium aluminum silicon carbide (TiAlSiC) film can be tuned by repeating one or more of the first cycle, the second cycle, or the third cycle. The amount of aluminum (Al) in at.% in the titanium aluminum silicon carbide (TiAlSiC) film can be tuned by controlling the temperature of the aluminum-containing precursor ampoule. The amount of aluminum (Al) in at.% in the titanium aluminum silicon carbide (TiAlSiC) film can be tuned by controlling the deposition temperature.

In specific embodiments, the first N-metal gate film 151 comprising the titanium aluminum silicon carbide (TiAlSiC) film has in a range of from 3 at.% to 10 at.% of silicon (Si). It has been advantageously found that in the range of from 3 at.% to 10 at.% of silicon (Si) in the first N-metal gate film 151 comprising the titanium aluminum silicon carbide (TiAlSiC) film maintains low resistivity and high electrical conductivity.

The tantalum-containing precursor can be any suitable precursor that includes tantalum (Ta). In one or more embodiments, the tantalum-containing precursor comprises tantalum pentachloride (TaCl₅).

The titanium-containing precursor can be any suitable precursor that includes titanium (Ti). In one or more embodiments, the titanium-containing precursor comprises titanium tetrachloride (TiCl₄).

The aluminum-containing precursor can be any suitable precursor that includes aluminum (Al). In one or more embodiments, the aluminum-containing precursor comprises triethylaluminum (TEA), trimethylaluminum (TMA), dimethylaluminum hydride (DMAH), tritertiarybutylaluminium (TTBA), or an alane (AlH₃), including, but not limited to dimethylethylamine alane (DMEAA).

The silicon-containing precursor can be any suitable precursor that includes silicon (Si). In one or more embodiments, the silicon-containing precursor comprises a silane, a disilane, or higher-order silanes. As used herein, “higher-order silanes” refer to silicon hydrides with more than two silicon atoms in their respective structures.

In accordance with operation 22 of the method 20 and operation 36 of the method 30, at least one N-metal gate film is deposited on the N-metal stack 150. A second N-metal gate film 152 is deposited on the first N-metal gate film 151 is shown in FIG. 2L.

The second N-metal gate film 152 has a tunable thickness configured to provide multiple threshold voltages (multi-Vₜ). In one or more embodiments, the second N-metal gate film 152 comprises a tunable composition, i.e., a binary metal carbide film, a binary metal silicide film, a ternary metal carbide film, or a ternary metal silicide film configured to provide multiple threshold voltages (multi-Vₜ). In one or more embodiments, the second N-metal gate film 152 has a tunable thickness configured to provide multiple threshold voltages (multi-Vₜ), and comprises a tunable composition, i.e., a binary metal carbide film, a binary metal silicide film, a ternary metal carbide film, or a ternary metal silicide film configured to provide multiple threshold voltages (multi-Vₜ).

In one or more embodiments, the first N-metal gate film 151 and the second N-metal gate film 152 are the same. In one or more embodiments, the first N-metal gate film 151 and the second N-metal gate film 152 are different. In one or more embodiments, the second N-metal gate film 152 is configured to provide a second threshold voltage (i.e., a second Vₜ).

In FIG. 2L, the fourth sacrificial layer 137 remains on the P-metal stack 155 and is configured to prevent deposition thereon.

In accordance with operation 22 of the method 20 and operation 36 of the method 30, at least one N-metal gate film is deposited on the N-metal stack 150. In FIG. 2M, a third N-metal gate film 153 is deposited on the second N-metal gate film 152 which is deposited on the first N-metal gate film 151.

The third N-metal gate film 153 has a tunable thickness configured to provide multiple threshold voltages (multi-Vₜ). In one or more embodiments, the third N-metal gate film 153 comprises a tunable composition, i.e., a binary metal carbide film, a binary metal silicide film, a ternary metal carbide film, or a ternary metal silicide film configured to provide multiple threshold voltages (multi-Vₜ). In one or more embodiments, the third N-metal gate film 153 has a tunable thickness configured to provide multiple threshold voltages, and comprises a tunable composition, i.e., a binary metal carbide film, a binary metal silicide film, a ternary metal carbide film, or a ternary metal silicide film configured to provide multiple threshold voltages (multi-Vₜ).

In some embodiments, one or more of the first N-metal gate film 151, the second N-metal gate film 152, or the third N-metal gate film 153 are the same. In some embodiments, each of the first N-metal gate film 151, the second N-metal gate film 152, and the third N-metal gate film 153 are the same. In some embodiments, each of the first N-metal gate film 151, the second N-metal gate film 152, and the third N-metal gate film 153 are different from one another. In one or more embodiments, the third N-metal gate film 153 is configured to provide a third threshold voltage (i.e., a third Vₜ).

In one or more embodiments, the first Vₜ of the first N-metal gate film 151, the second Vₜ of the second N-metal gate film 152, and the third Vₜ of the third N-metal gate film 153 are provided by varying the composition of the first N-metal gate film 151, the second N-metal gate film 152, and the third N-metal gate film 153, respectively.

In FIG. 2N, the fourth sacrificial layer 137 is removed from the P-metal stack 155. The N-metal stack 150 includes the first N-metal gate film 151, the second N-metal gate film 152, and the third N-metal gate film 153.

In some embodiments, each of the at least one N-metal gate films independently has a thickness in a range of from greater than or equal to 1 nm to less than or equal to 3 nm. Advantageously, the at least one N-metal gate films are configured to be deposited in the scaled space between one or more nanosheets. In one or more embodiments, the at least one N-metal gate film (e.g., the first N-metal gate film 151, the second N-metal gate film 152, and the third N-metal gate film 153) collectively have a thickness in a range of from greater than or equal to 1 nm to less than or equal to 3 nm and are deposited in the space between each nanosheet layer in the N-metal stack 150.

FIG. 2N illustrates the semiconductor device 100 (e.g., the electronic device) including the P-metal stack 155 with multiple threshold voltages (by way of the at least one P-metal gate film, e.g., the first P-metal gate film 156, the second P-metal gate film 157, and the third P-metal gate film 158) and the N-metal stack 150 having multiple threshold voltages (by way of the at least one N-metal gate film, e.g., the first N-metal gate film 151, the second N-metal gate film 152, and the third N-metal gate film 153).

In specific embodiments where the P-metal stack 155 includes the first P-metal gate film 156, the second P-metal gate film 157, and the third P-metal gate film 158 and the N-metal stack 150 includes the first N-metal gate film 151, the second N-metal gate film 152, and the third N-metal gate film 153, the P-metal stack 155 has three threshold voltages (i.e., the first Vₜ of the first P-metal gate film 156, the second Vₜ of the second P-metal gate film 157, and the third Vₜ of the third P-metal gate film 158) and the N-metal stack 150 has three threshold voltages (i.e., the first Vₜ of the first N-metal gate film 151, the second Vₜ of the second N-metal gate film 152, and the third Vₜ of the third N-metal gate film 153).

The methods described herein can be performed in any suitable processing system. In one or more embodiments, each of the operations of the methods described herein are performed in situ in an integrated processing system. In one or more embodiments, one or more of the operations of the methods described herein are performed ex situ. The particular arrangement of processing chambers and components can be varied depending on the processing system and should not be taken as limiting the scope of the disclosure.

Embodiments of the disclosure are directed to a non-transitory computer readable medium. In one or more embodiments, the non-transitory computer readable medium includes instructions that, when executed by a controller of a processing system, causes the processing system to perform the operations of any of the methods described herein.

Although the disclosure herein has been described with reference to particular embodiments, it is to be understood that these embodiments are merely illustrative of the principles and applications of the disclosure. It will be apparent to those skilled in the art that various modifications and variations can be made to the method and apparatus of the present disclosure without departing from the spirit and scope of the disclosure. Thus, it is intended that the present disclosure include modifications and variations that are within the scope of the appended claims and their equivalents.

What is claimed is:

1. A method of manufacturing a semiconductor device, the method comprising:
forming a P-metal stack and an N-metal stack on a substrate, each of the P-metal stack and the N-metal stack formed on a channel located between a source and a drain on the substrate, each of the P-metal stack and the N-metal stack independently comprising an interfacial layer on the channel and a high-ĸ dielectric layer on the interfacial layer; and
depositing at least one P-metal gate film on the P-metal stack, each of the at least one P-metal gate films independently including one or more of:
a tunable thickness configured to provide multiple threshold voltages, or
a binary metal nitride film or a ternary metal nitride film configured to provide multiple threshold voltages.

2. A method of manufacturing a semiconductor device, the method comprising:
forming a P-metal stack and an N-metal stack on a substrate, each of the P-metal stack and the N-metal stack formed on a channel located between a source and a drain on the substrate, each of the P-metal stack and the N-metal stack independently comprising an interfacial layer on the channel and a high-ĸ dielectric layer on the interfacial layer; and
depositing at least one N-metal gate film on the N-metal stack, each of the at least one N-metal gate films independently including one or more of:
a tunable thickness configured to provide multiple threshold voltages, or
a binary metal carbide film, a binary metal silicide film, a ternary metal carbide film, or a ternary metal silicide film configured to provide multiple threshold voltages.

3. A method of manufacturing a semiconductor device, the method comprising:
forming a P-metal stack and an N-metal stack on a substrate, each of the P-metal stack and the N-metal stack formed on a channel located between a source and a drain on the substrate, each of the P-metal stack and the N-metal stack independently comprising an interfacial layer on the channel and a high-ĸ dielectric layer on the interfacial layer;
depositing at least one P-metal gate film on the P-metal stack, each of the at least one P-metal gate films independently including one or more of:
a tunable thickness configured to provide multiple threshold voltages, or
a binary metal nitride film or a ternary metal nitride film configured to provide multiple threshold voltages; and
depositing at least one N-metal gate film on the N-metal stack, each of the at least one N-metal gate films independently including one or more of:
a tunable thickness configured to provide multiple threshold voltages, or
a binary metal carbide film, a binary metal silicide film, a ternary metal carbide film, or a ternary metal silicide film configured to provide multiple threshold voltages.

4. The method of claim 3, further comprising sequentially performing the following operations prior to depositing the at least one P-metal gate film:
depositing a first sacrificial layer on the P-metal stack and the N-metal stack;
selectively removing the first sacrificial layer from the P-metal stack;
depositing a first n-type dipole layer or a first p-type dipole layer on the P-metal stack;
annealing the P-metal stack to drive atoms from the first n-type dipole layer or the first p-type dipole layer into an interface between the high-ĸ dielectric layer and the interfacial layer; and
removing the first n-type dipole layer or the first p-type dipole layer.

5. The method of claim 4, further comprising sequentially performing the following operations prior to depositing the at least one N-metal gate film on the N-metal stack:
depositing a second sacrificial layer on the P-metal stack;
selectively removing the first sacrificial layer from the N-metal stack;
depositing a second n-type dipole layer or a second p-type dipole layer on the N-metal stack;
annealing the N-metal stack to drive atoms from the second n-type dipole layer or the second p-type dipole layer into an interface between the high-ĸ dielectric layer and the interfacial layer; and
removing the second n-type dipole layer or the second p-type dipole layer.

6. The method of claim 5, wherein annealing the P-metal stack and the N-metal stack comprises an in situ rapid thermal process (RTP).

7. The method of claim 6, further comprising removing the second sacrificial layer from the P-metal stack.

8. The method of claim 3, wherein the interfacial layer comprises a dielectric material selected from one or more of silicon (Si), silicon oxide (SiOx), hydrogenated silicon oxide, doped silicon, doped silicon oxide, or spin-on dielectrics.

9. The method of claim 3, wherein the high-ĸ dielectric layer comprises one or more of hafnium oxide (HfOx), zirconium oxide (ZrOx), or hafnium zirconium oxide (HfZrOx).

10. The method of claim 7, wherein each of the first p-type dipole layer and the second p-type dipole layer independently comprises one or more of aluminum (Al), zinc (Zn), gallium (Ga), indium (In), tin (Sn), antimony (Sb), tellurium (Te), niobium (Nb), molybdenum (Mo), tantalum (Ta), tungsten (W), germanium (Ge), bismuth (Bi), selenium (Se), carbides thereof, or nitrides thereof.

11. The method of claim 7, wherein each of the at least one P-metal gate films independently include the binary metal nitride film or the ternary metal nitride film configured to provide multiple threshold voltages.

12. The method of claim 11, wherein each of the at least one P-metal gate films independently has a formula of MXN, where M is a first metal selected from the group consisting of hafnium (Hf), magnesium (Mg), lanthanum (La), yttrium (Y), aluminum (Al), manganese (Mn), zirconium (Zr), tantalum (Ta), vanadium (V), zinc (Zn), titanium (Ti), niobium (Nb), tin (Sn), tungsten (W), molybdenum (Mo), ruthenium (Ru), and antimony (Sb), X is a second metal selected from the group consisting of hafnium (Hf), magnesium (Mg), lanthanum (La), yttrium (Y), aluminum (Al), manganese (Mn), zirconium (Zr), tantalum (Ta), vanadium (V), zinc (Zn), titanium (Ti), niobium (Nb), tin (Sn), tungsten (W), molybdenum (Mo), ruthenium (Ru), and antimony (Sb), the second metal is different from the first metal, and N is nitrogen.

13. The method of claim 12, wherein X is in a range of from 0 at.% to 40 at.%.

14. The method of claim 7, wherein each of the first n-type dipole layer and the second n-type dipole layer independently comprises one or more of lanthanum (La), strontium (Sr), scandium (Sc), yttrium (Y), zirconium (Zr), ytterbium (Yb), or barium (Ba).

15. The method of claim 14, wherein each of the at least one N-metal gate films independently include the binary metal carbide film, the binary metal silicide film, the ternary metal carbide film, or the ternary metal silicide film configured to provide multiple threshold voltages.

16. The method of claim 14, wherein each of the at least one N-metal gate films independently comprises titanium silicide (TiSi), tantalum silicide (TaSi), aluminum silicide (AlSi), lanthanum silicide (LaSi), zirconium silicide (ZrSi), yttrium silicide (YSi), ytterbium silicide (YbSi), scandium silicide (ScSi), lanthanum silicide (LaSi), titanium carbide (TiC), tantalum carbide (TaC), aluminum carbide (AlC), lanthanum carbide (LaC), zirconium carbide (ZrC), yttrium carbide (YC), ytterbium carbide (YbC), scandium carbide (ScC), lanthanum carbide (LaC), or combinations thereof.

17. The method of claim 15, wherein each of the at least one N-metal gate films independently comprises titanium aluminum carbide (TiAlC), titanium aluminum silicide (TiAlSi), tantalum aluminum carbide (TaAlC), tantalum aluminum silicide (TaAlSi), zirconium aluminum silicide (ZrAlSi), yttrium aluminum silicide (YAlSi), ytterbium aluminum silicide (YbAlSi), scandium aluminum silicide (ScAlSi), lanthanum aluminum silicide (LaAlSi), zirconium aluminum carbide (ZrAlC), yttrium aluminum carbide (YAlC), ytterbium aluminum carbide (YbAlC), scandium aluminum carbide (ScAlC), or lanthanum aluminum carbide (LaAlC), or combinations thereof.

18. The method of claim 3, wherein the channel of each of the P-metal stack and the N-metal stack independently comprises a plurality of nanosheet channel layers including a space between each nanosheet channel layer.

19. The method of claim 18, wherein the at least one P-metal gate film is deposited in the space between each nanosheet channel layer in the P-metal stack.

20. The method of claim 18, wherein the at least one N-metal gate film is deposited in the space between each nanosheet channel layer in the N-metal stack.
